(19) United States
(12) Patent Application Publication
(10) Pub. No.: US 2025/0393183 A1
(43) Pub. Date: Dec. 25, 2025

(54) Semiconductor Device Structure and Related Methods

(71) Applicant: Taiwan Semiconductor Manufacturing Company, Ltd., Hsin-Chu (TW)

(72) Inventor: Tzu-Ging LIN, Kaohsiung City (TW)

(21) Appl. No.: 18/961,701

(22) Filed: Nov. 27, 2024

Related U.S. Application Data
(60) Provisional application No. 63/663,886, filed on Jun. 25, 2024.

(51) Int. Cl. H10B 10/00

(52) U.S. Cl. CPC H10B 10/125

(57) ABSTRACT

Methods and structures for performing isolation patterning processes include defining a plurality of active regions extending in a first direction in a top-down view. The method further includes forming a plurality of dummy gate structures over the plurality of active regions, the plurality of dummy gate structures extending in a second direction in the top-down view, the second direction perpendicular to the first direction. The method further includes forming a plurality of source/drain features in source/drain regions adjacent to and on either side of each dummy gate structure of the plurality of dummy gate structures. The method further includes replacing the plurality of dummy gate structures with a plurality of high-K/metal gate stacks. The method further includes forming an isolation structure within a high-K/metal gate stack, where the isolation structure has first and second source/drain features disposed on either side of the isolation structure.

### CROSS-REFERENCE TO RELATED APPLICATION

This application claims the benefit of U.S. Provisional Application No. 63/663,886, filed Jun. 25, 2024, the entirety of which is incorporated by reference herein.

### BACKGROUND

The electronics industry has experienced an ever-increasing demand for smaller and faster electronic devices which are simultaneously able to support a greater number of increasingly complex and sophisticated functions. Accordingly, there is a continuing trend in the semiconductor industry to manufacture low-cost, high-performance, and low-power integrated circuits (ICs). Thus far these goals have been achieved in large part by scaling down semiconductor IC dimensions (e.g., minimum feature size) and thereby improving production efficiency and lowering associated costs. However, such scaling has also introduced increased complexity to the semiconductor manufacturing process. Thus, the realization of continued advances in semiconductor ICs and devices calls for similar advances in semiconductor manufacturing processes and technology.

Recently, multi-gate devices have been introduced in an effort to improve gate control by increasing gate-channel coupling, reduce OFF-state current, and reduce short-channel effects (SCEs). One such multi-gate device that has been introduced is the fin field-effect transistor (FinFET). The FinFET gets its name from the fin-like structure which extends from a substrate on which it is formed, and which is used to form the FET channel. Another multi-gate device, introduced in part to address performance challenges associated with FinFETs, is the gate-all-around (GAA) transistor. GAA transistors get their name from the gate structure which extends completely around the channel, providing better electrostatic control than FinFETs. FinFETs and GAA transistors are compatible with conventional complementary metal-oxide-semiconductor (CMOS) processes and their three-dimensional structure allows them to be aggressively scaled while maintaining gate control and mitigating SCEs.

In general, GAA transistors may be implemented, for example, in cases where FinFETs can no longer meet performance requirements. However, fabrication of GAA transistors has introduced new challenges to the semiconductor manufacturing process and has led to associated device reliability concerns. Thus, existing techniques have not proved entirely satisfactory in all respects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 provides a simplified top-down layout view of a multi-gate device, in accordance with some embodiments;

FIG. 2 provides an exemplary circuit diagram of an SRAM cell, in accordance with some embodiments;

FIG. 3 is a flow chart of a method of fabricating a memory device, according to one or more aspects of the present disclosure;

FIGS. 4A, 4B, 4C, 4D, and 4E provide top-down views of an embodiment of a memory device at various stages of fabrication according to the method of FIG. 3, in accordance with some embodiments;

FIG. 5 is a flow chart of an alternative method of fabricating a memory device, according to one or more aspects of the present disclosure;

FIGS. 6A, 6B, 6C, 6D, 6E, 6F, 6G, and 6H provide top-down views of an embodiment of a memory device at various stages of fabrication according to the method of FIG. 5, in accordance with some embodiments;

FIG. 7 is a flow chart of a method of fabricating a semiconductor device, according to one or more aspects of the present disclosure;

FIGS. 8A, 9A, 10A, 11A, 12A, and 13A provide cross-sectional views, at various stages of fabrication according to the method of FIG. 7, of an embodiment of a semiconductor device along a plane substantially parallel to a plane defined by section AA′ of FIG. 1;

FIGS. 8B, 9B, 10B, 11B, 12B, and 13B provide cross-sectional views, at various stages of fabrication according to the method of FIG. 7, of an embodiment of a semiconductor device along a plane substantially parallel to a plane defined by section BB′ of FIG. 1;

FIG. 14 is a flow chart of an alternative method of fabricating a semiconductor device, according to one or more aspects of the present disclosure;

FIGS. 15A, 16A, 17A, 18A, 19A, 20A, 21A, 22A, 23A, 24A, 25A, 26A, 27A, 28A, 29A, 30A, and 31A provide cross-sectional views, at various stages of fabrication according to the method of FIG. 14, of an embodiment of a semiconductor device along a plane substantially parallel to a plane defined by section AA′ of FIG. 1; and

FIGS. 15B, 16B, 17B, 18B, 19B, 20B, 21B, 22B, 23B, 24B, 25B, 26B, 27B, 28B, 29B, 30B, and 31B provide cross-sectional views, at various stages of fabrication according to the method of FIG. 14, of an embodiment of a semiconductor device along a plane substantially parallel to a plane defined by section BB′ of FIG. 1.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Additionally, in the discussion that follows, dimensions (e.g., such as thickness, width, length, etc.) for a given layer or other feature may at times be described using terms such as “substantially equal”, “equal”, or “about”, where such terms are understood to mean within +/−10% of the recited value or between compared values. For instance, if dimension A is described as being “substantially equal” to dimension B, it will be understood that dimension A is within +/−10% of dimension B. As another example, if a layer is described as having a thickness of about 100 nm, it will be understood that the thickness of the layer may in a range between 90-110 nm.

It is also noted that the present disclosure presents embodiments in the form of multi-gate transistors which may be employed in any of a variety of device types and/or circuit types. Multi-gate transistors include those transistors whose gate structures are formed on at least two-sides of a channel region. These multi-gate devices may include a P-type transistor or an N-type transistor. Specific examples may be presented and referred to herein as fin field-effect transistors (FinFETs), on account of their fin-like structure. FinFET devices may include fins extending from a substrate (or nanostructures extending from a substrate), where the fins are composed of a substantially uniform composition. Also presented herein are embodiments of a type of multi-gate transistor referred to as a gate-all-around (GAA) transistor. A GAA transistor includes any device that has its gate structure, or portion thereof, formed on 4-sides of a channel region (e.g., surrounding a portion of a channel region). Devices presented herein also include embodiments that have channel regions disposed in various nanostructures such as nanosheet channel(s), nanowire channel(s), bar-shaped channel(s), and/or other suitable channel configurations. Presented herein are embodiments of devices that may have one or more nanostructured channel regions (e.g., nanowires/nanosheets) associated with a single, contiguous gate structure. GAA devices may include a plurality of stacked channel layers (e.g., a plurality of stacked nanosheets) that form the channels of a GAA transistor. However, one of ordinary skill would recognize that the teachings disclosed herein can apply to a single channel (e.g., single nanowire/nanosheet) or any number of channels. One of ordinary skill may recognize other examples of semiconductor devices that may benefit from aspects of the present disclosure.

The present disclosure is generally related the minimization of layout-dependent effects (LDEs) in state-of-the-art CMOS circuits to meet aggressive scaling requirements. More particularly, aspects of the present disclosure are related to the formation of isolation structures in a highly symmetric process environment to minimize LDEs. In the course of fabrication of semiconductor circuits, various isolation patterning processes may be performed to isolate metal lines and/or active regions to define circuit patterns. In some existing implementations, isolation patterning processes are suboptimal and lead to increased LDEs. As one example, during the fabrication of static random-access memory (SRAM) circuits, active regions (where device channels are formed) may be cut (isolated) prior to formation of dummy poly gates, resulting in an asymmetric or non-uniform wafer environment composed of the broken up active regions. This asymmetry can cause stress and lead to poor active region line edge roughness (LER). Dummy poly gates may then be formed over the asymmetric or cut active regions, which can lead to poor polysilicon LER. Thereafter, epitaxial source/drain features may be formed, where such source/drain features may be designed to provide stress to device channels. However, due to the asymmetric or non-uniform wafer environment in which the epitaxial source/drain features are formed, there may be a loss of stress applied by the source/drain features and a corresponding drop in device performance. After formation of the epitaxial source/drain features, the dummy poly gates may be replaced with a metal gate stack. In some cases, however, the metal gate stack may suffer from metal gate tilting due to the asymmetric or non-uniform wafer environment. A metal gate patterning process (cut metal gate process) may then be performed to form isolation regions that isolate various sections of different metal gate stacks. Such a gate patterning process may lead to high parasitic capacitance, for example, due to the close proximity of metal layers of adjacent metal gate stacks disposed on opposite sides of a respective isolation region. Thus, existing techniques have not proved entirely satisfactory in all respects.

Embodiments of the present disclosure offer advantages over the existing art, though it is understood that other embodiments may offer different advantages, not all advantages are necessarily discussed herein, and no particular advantage is required for all embodiments. For example, embodiments discussed herein include methods and structures for performing isolation patterning processes in highly-scaled CMOS circuits, to address various existing challenges (such as minimization of LDEs). While not limited thereto, aspects of the present disclosure may be used to perform isolation structures within, and thus to pattern, SRAM circuits. In various embodiments, the disclosed isolation patterning processes may be performed using a continuous metal on diffusion edge (CMODE) patterning process, a continuous poly on diffusion edge (CPODE) patterning process, or a combination of a CPODE patterning process and a cut metal gate (CMG) patterning process. As part of the CMODE process, and after formation of a metal gate stack, a trench may be formed through a portion of the metal gate stack and extending into the substrate, and the trench is filled with a dielectric material, thereby providing isolation between adjacent portions of the metal gate stack. As part of the CPODE process, after formation of a dummy poly gate and prior to forming a metal gate stack, a trench may be formed through a portion of the dummy poly gate and extending into the substrate, and the trench is filled with a dielectric material, thereby providing isolation between adjacent portions of the dummy poly gate. In some cases, when a CPODE process is performed and after replacing the dummy poly gate with a metal gate stack, a CMG process may be performed to remove high-K gate dielectric portions from metal line end regions of the metal gate stack in order to reduce parasitic capacitance by minimizing metal boundary effects (MBEs).

Considering once again the example of fabrication of SRAM circuits, and in accordance with some embodiments, fabrication processes that employ the CMODE patterning process include: (i) no patterning (no cutting) of active regions prior to formation of dummy poly gates, thereby maintaining a symmetric or uniform wafer environment over which dummy poly gates are formed and providing for improved polysilicon LER; (ii) formation of epitaxial source/drain features in a symmetric or uniform wafer environment, which provides for minimization of loss of stress applied by the source/drain features; (iii) replacing the dummy poly gates with a metal gate stack; and (iv) CMODE patterning to provide isolation between adjacent portions of the metal gate stack. Due to the symmetric or uniform wafer environment which includes the metal gate stacks, the risk of metal gate tilting is also minimized.

In another example of fabrication of SRAM circuits, and in accordance with some embodiments, fabrication processes that employ the CPODE patterning process include: (i) no patterning of active regions prior to formation of dummy poly gates to maintain a symmetric or uniform wafer environment over which dummy poly gates are formed, thereby providing for improved polysilicon LER; (ii) formation of epitaxial source/drain features in a symmetric or uniform wafer environment, which provides for minimization of loss of stress applied by the source/drain features; (iii) CPODE patterning to provide isolation between adjacent portions of the dummy poly gates; (iv) replacing the dummy poly gates with a metal gate stack; and (iv) optionally performing CMG patterning to remove high-K gate dielectric portions from metal line end regions of the metal gate stack in order to reduce parasitic capacitance by minimizing MBEs. Embodiments of the present disclosure thus effectively mitigate LDEs, as compared to existing implementations. Other embodiments and advantages will be evident to those skilled in the art upon reading the present disclosure.

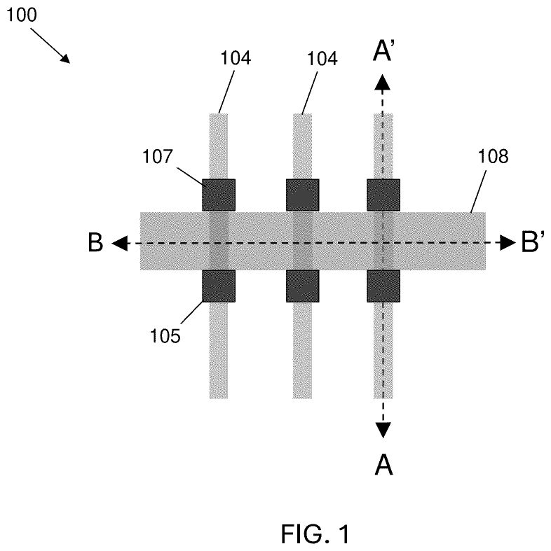

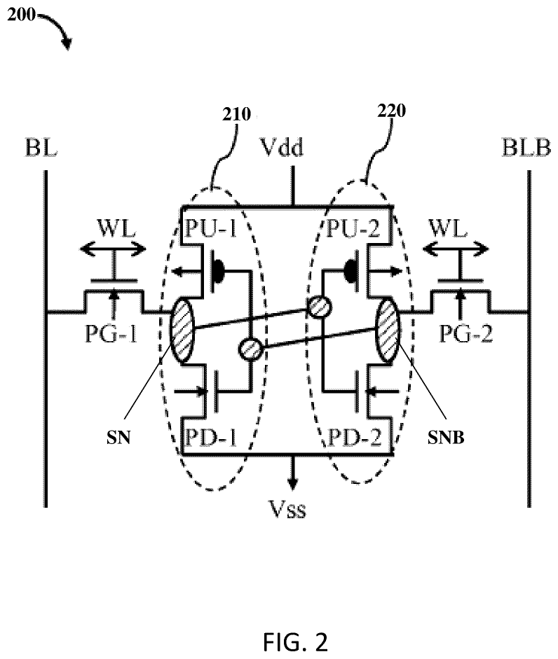

Because one or more of the embodiments described herein are exemplified using multi-gate transistors (e.g., such as FinFETs or GAA devices) and SRAM devices, a description of such devices is provided below with respect to FIG. 1 and FIG. 2. However, it should be understood that the descriptions given below with respect to multi-gate transistors and SRAM devices are merely exemplary, and other types of devices and/or circuits may benefit from one or more of the embodiments described herein.

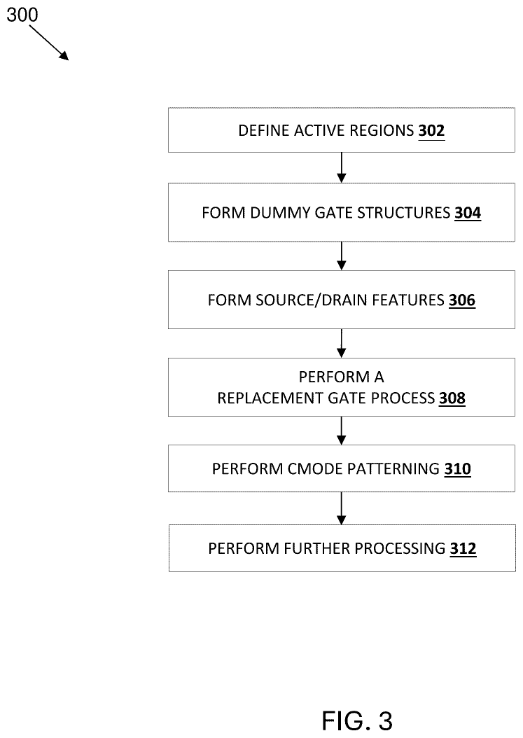

FIG. 1 provides a simplified top-down layout view of a multi-gate device 100. In various embodiments, the multi-gate device 100 may include a FinFET device, a GAA device, or other type of multi-gate device. The multi-gate device 100 may include a plurality of fin elements 104 extending from a substrate, a gate structure 108 disposed over and around the fin elements 104, and source/drain regions 105, 107, where the source/drain regions 105, 107 are formed in, on, and/or surrounding the fins 104. A channel region of the multi-gate device 100 is disposed within the fins 104, underlying the gate structure 108, along a plane substantially parallel to a plane defined by section AA′ of FIG. 1. When the multi-gate device 100 includes a FinFET device, the channel region may include a fin (or nanostructure) extending from a substrate, where the fin (or nanostructure) is composed of a substantially uniform composition. When the multi-gate device 100 includes a GAA device, the channel region may include a plurality of semiconductor channel layers (e.g., such as a plurality of stacked nanostructures or stacked nanosheets). In some embodiments, sidewall spacers may also be formed on sidewalls of the gate structure 108. Various other features of the multi-gate device 100 are discussed in more detail below with reference to the methods of FIGS. 3, 5, 7, and 14.

Referring to FIG. 2, illustrated therein is an exemplary circuit diagram of an SRAM cell 200, which can be implemented in a memory cell of a SRAM array, according to various aspects of the present disclosure. While FIG. 2 illustrates a single-port SRAM cell, it will be understood that the various disclosed embodiments may be equally implemented in a multi-port SRAM cell (e.g., such as a dual-port SRAM cell), without departing from the scope of the present disclosure. FIG. 2 has been simplified for the sake of clarity to better understand the inventive concepts of the present disclosure. Additional features can be added in the SRAM cell 200, and some of the features described below can be replaced, modified, or eliminated in other embodiments of SRAM cell 200.

The SRAM cell 200 includes six transistors: a pass-gate transistor PG-1, a pass-gate transistor PG-2, a pull-up transistor PU-1, a pull-up transistor PU-2, a pull-down transistor PD-1, and a pull-down transistor PD-2. Thus, in some examples, the SRAM cell 200 may be referred to as a 6T SRAM cell. In operation, pass-gate transistor PG-1 and pass-gate transistor PG-2 provide access to a storage portion of the SRAM cell 200, which includes a cross-coupled pair of inverters, an inverter 210 and an inverter 220. Inverter 210 includes the pull-up transistor PU-1 and the pull-down transistor PD-1, and inverter 220 includes the pull-up transistor PU-2 and the pull-down transistor PD-2. In some implementations, pull-up transistors PU-1, PU-2 are configured as P-type transistors (e.g., such as FinFETs or GAA devices), and pull-down transistors PD-1, PD-2 are configured as N-type transistors (e.g., such as FinFETs or GAA devices). In some implementations, pass-gate transistors PG-1, PG-2 are also configured as N-type transistors (e.g., such as FinFETs or GAA devices).

A gate of pull-up transistor PU-1 interposes a source (electrically coupled with a power supply voltage (VDD)) and a first common drain (CD1), and a gate of pull-down transistor PD-1 interposes a source (electrically coupled with a power supply voltage (VSS)) and the first common drain. A gate of pull-up transistor PU-2 interposes a source (electrically coupled with power supply voltage (VDD)) and a second common drain (CD2), and a gate of pull-down transistor PD-2 interposes a source (electrically coupled with power supply voltage (VSS)) and the second common drain. In some implementations, the first common drain (CD1) is a storage node (SN) that stores data in true form, and the second common drain (CD2) is a storage node (SNB) that stores data in complementary form. The gate of pull-up transistor PU-1 and the gate of pull-down transistor PD-1 are coupled with the second common drain, and the gate of pull-up transistor PU-2 and the gate of pull-down transistor PD-2 are coupled with the first common drain. A gate of pass-gate transistor PG-1 interposes a source (electrically coupled with a bit line BL) and a drain, which is electrically coupled with the first common drain. A gate of pass-gate transistor PG-2 interposes a source (electrically coupled with a complementary bit line BLB) and a drain, which is electrically coupled with the second common drain. The gates of pass-gate transistors PG-1, PG-2 are electrically coupled with a word line WL. In some implementations, pass-gate transistors PG-1, PG-2 provide access to storage nodes SN, SNB during read operations and/or write operations. For example, pass-gate transistors PG-1, PG-2 couple storage nodes SN, SN-B respectively to bit lines BL, BLB in response to voltage applied to the gates of pass-gate transistors PG-1, PG-2 by WLs.

In view of the above discussion with respect to FIGS. 1 and 2, various embodiments of the present disclosure are now described. It is understood that the various figures, and any accompanying descriptions given, are merely exemplary and are not intended to be limiting beyond what is specifically recited in the claims that follow. In addition, the various figures shown and described have been simplified for the sake of clarity to better understand the inventive concepts of the present disclosure, and various features may be added, replaced, modified, or eliminated, without departing from the scope of the present disclosure.

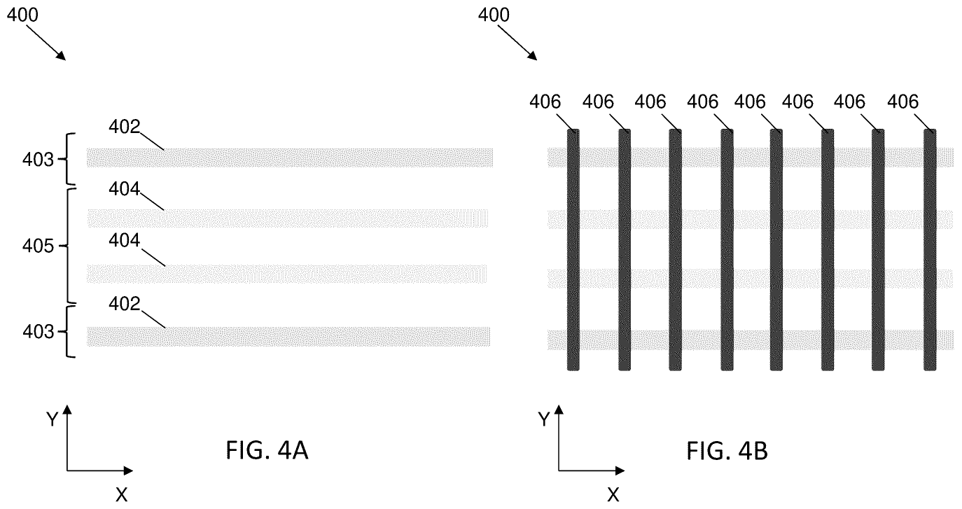

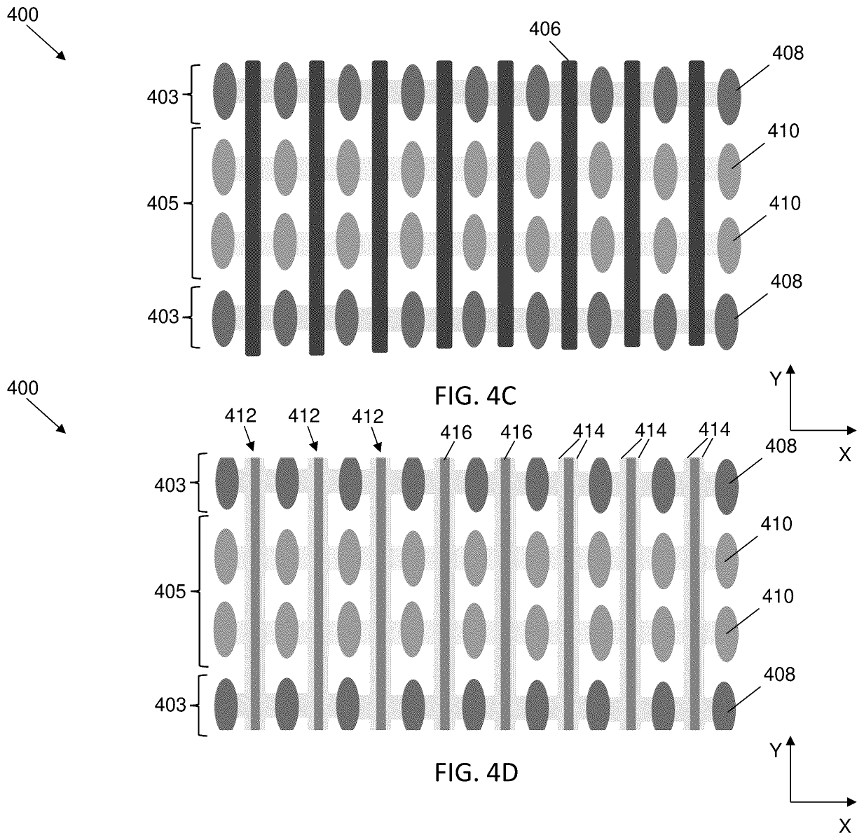

Referring now to FIG. 3, illustrated therein is a method 300 of semiconductor fabrication including fabrication of a memory device 400 (e.g., which includes an SRAM circuit) using a CMODE patterning process, in accordance with various embodiments. The method 300 is described below with reference to FIGS. 4A-4E, which provide top-down views of an embodiment of the memory device 400 at various stages of fabrication according to the method 300. It will be understood that aspects of the method 300 may be applied to devices or circuits implemented using various types of multi-gate devices, such as FinFETs, GAA transistors (or nanosheet transistors), other types of advanced transistor devices, or combinations thereof, without departing from the scope of the present disclosure. In some embodiments, the method 300 may be used to fabricate the multi-gate device 100 described above with reference to FIG. 1 or the SRAM cell 200 described above with reference to FIG. 2. Thus, one or more aspects discussed above with reference to the multi-gate device 100, or with reference to the SRAM cell 200, may also apply to the method 300 and to the memory device 400. It is understood that the method 300 includes steps having features of a CMOS technology process flow and thus, are only described briefly herein. Also, additional steps may be performed before, after, and/or during the method 300.

It is further noted that, in some embodiments, the memory device 400 may include various other devices and features, such as other types of devices such as additional transistors, bipolar junction transistors, resistors, capacitors, inductors, diodes, fuses and/or other logic circuits, etc., but is simplified for a better understanding of the inventive concepts of the present disclosure. In some embodiments, the memory device 400 may include a plurality of semiconductor devices (e.g., transistors) which may be interconnected to form a circuit, such as an SRAM circuit. Moreover, it is noted that the process steps of method 300, including any descriptions given with reference to the figures are merely exemplary and are not intended to be limiting beyond what is specifically recited in the claims that follow.

The method 300 begins at block 302 where active regions are defined in a substrate. With reference to FIG. 4A, in an embodiment of block 302, active regions 402 and active regions 404 are defined. In an example, the active regions 402, 404 extend along an X-direction, as shown. The active regions 402, 404 include regions where transistor channels and epitaxial source/drain features will be formed. In the illustrated example, the active regions 402 may be formed in an N-type device region 403, and the active regions 404 may be formed in a P-type device region 405. In various embodiments, respective ones of the active regions 402, 404 may be separated from each other by a shallow trench isolation (STI) feature. In some cases, for instance when FinFETs are to be used to fabricate the memory device 400, the active regions 402, 404 may include fins extending from a substrate (or nanostructures extending from a substrate), where the fins are composed of a substantially uniform composition. In other examples, for instance when GAA transistors (or nanosheet transistors) are to be used to fabricate the memory device 400, the active regions 402, 404 may include a plurality of stacked channel layers (or a plurality of stacked nanosheets) that are stacked over the substrate and which form the channels of a GAA transistor. It is also noted that after formation of the active regions 402, 404, the active regions 402, 404 are not patterned (or cut). As a result, and as illustrated in the top-down view of FIG. 4A, the active regions 402, 404 provide symmetric patterns, in both an X-direction and a Y-direction, over the underlying substrate. Stated another way, a process environment (which includes a topography defined by features formed over the underlying substrate) is symmetric. In the present example, the symmetric process environment, as shown in the top-down view of FIG. 4A, includes an array of repeating shapes (or a repeating pattern) composed of the active regions 402, 404. During processing of the memory device 400, and in accordance with the embodiments disclosed herein, the symmetric process environment serves to effectively mitigate LDEs, as compared to existing implementations.

The memory device 400, and thus the active regions 402, 404, may be formed on a substrate, as described above. In some embodiments, the substrate may be a semiconductor substrate such as a silicon substrate. The substrate may include various layers, including conductive or insulating layers formed on a semiconductor substrate. The substrate may include various doping configurations depending on design requirements as is known in the art. The substrate may also include other semiconductors such as germanium, silicon carbide (SiC), silicon germanium (SiGe), or diamond. Alternatively, the substrate may include a compound semiconductor and/or an alloy semiconductor. Further, the substrate may optionally include an epitaxial layer (epi-layer), may be strained for performance enhancement, may include a silicon-on-insulator (SOI) structure, and/or have other suitable enhancement features.

The method 300 proceeds to block 304 where dummy gate structures are formed. With reference to FIG. 4A and FIG. 4B, in an embodiment of block 304, a plurality of dummy gate structures 406 are formed over the active regions 402, 404. As shown, the dummy gate structures 406 extend in the Y-direction, as shown, which is perpendicular to the direction (X-direction) in which the active regions 402, 404 extend. In some embodiments, the dummy gate structures 406 each include a dummy gate dielectric and a dummy gate electrode. The dummy gate dielectric includes a dielectric material, such as silicon oxide, a high-K dielectric material, other suitable dielectric material, or a combination thereof. The dummy gate electrode includes a suitable dummy gate material, such as polysilicon. In various embodiments, and due to the symmetric process environment provided by the symmetric patterns of the active regions 402, 404 over which the dummy gate structures 406 are formed, the dummy gate structures 406 will have a good polysilicon line edge roughness (LER). The dummy gate structures 406 will be replaced at a later stage of processing, for example as part of a replacement gate process, by a high-K/metal gate stack. It is noted that after formation of the dummy gate structures 406, and as illustrated in the top-down view of FIG. 4B, the dummy gate structures 406 and the active regions 402, 404 maintain symmetric patterns, in both the X-direction and the Y-direction. Stated another way, the process environment remains symmetric after formation of the dummy gate structures 406 and continues to benefit subsequent processing, as discussed below. In the present example, the symmetric process environment, as shown in the top-down view of FIG. 4B, includes a first array of repeating shapes (composed of the active regions 402, 404) and a second array of repeating shapes (composed of the dummy gate structures 406).

The method 300 proceeds to block 306 where source/drain features are formed. With reference to FIG. 4B and FIG. 4C, in an embodiment of block 306 and after formation of the dummy gate structures 406, source/drain features are formed in the source/drain regions adjacent to and on either side of the dummy gate structures 406. For example, source/drain features 408 may be formed within the N-type device regions 403 over the active regions 402, on either side of the dummy gate structures 406, and in contact with the channel regions of N-type transistors (e.g., such as N-type FinFETs or N-type GAA devices) formed in the N-type device regions 403. Similarly, source/drain features 410 may be formed within the P-type device region 405 over the active regions 404, on either side of the dummy gate structures 406, and in contact with the channel regions of P-type transistors (e.g., such as P-type FinFETs or P-type GAA devices) formed in the P-type device region 405. More particularly, the symmetric process environment is maintained by formation of source/drain features (either the source/drain features 408 or the source/drain features 410) over respective active regions 402, 404 on either side of each of the dummy gate structures 406.

In some embodiments, the source/drain features 408, 410 are formed by epitaxially growing a semiconductor material layer in the source/drain regions. In various embodiments, the semiconductor material layer grown to form the source/drain features 408, 410 may include Ge, Si, GaAs, AlGaAs, SiGe, GaAsP, SiP, or other suitable material. The source/drain features 408, 410 may be formed by one or more epitaxial (cpi) processes. In some embodiments, the source/drain features 408, 410 may be in-situ doped during the epi process. For example, in some embodiments, epitaxially grown SiGe source/drain features may be doped with boron. In some cases, epitaxially grown Si epi source/drain features may be doped with carbon to form Si:C source/drain features, phosphorous to form Si:P source/drain features, or both carbon and phosphorous to form SiCP source/drain features. In some embodiments, the source/drain features 408, 410 are not in-situ doped, and instead an implantation process is performed to dope the source/drain features 408, 410.

In various embodiments, and due to the symmetric process environment provided by the symmetric patterns of the dummy gate structures 406 and the active regions 402, 404, formation of the source/drain features 408, 410 can be performed with minimal loss of stress applied by the source/drain features 408, 410 onto the channel regions of respective ones of the N-type transistors and the P-type transistors. After formation of the source/drain features 408, 410, and as illustrated in the top-down view of FIG. 4C, the source/drain features 408, 410, the dummy gate structures 406, and the active regions 402, 404 maintain symmetric patterns, in both the X-direction and the Y-direction. Stated another way, the process environment remains symmetric after formation of the source/drain features 408, 410. In the present example, the symmetric process environment, as shown in the top-down view of FIG. 4C, includes the first array of repeating shapes (composed of the active regions 402, 404), the second array of repeating shapes (composed of the dummy gate structures 406), and a third array of repeating shapes (composed of the source/drain features 408, 410).

The method 300 proceeds to block 308 where a replacement gate process is performed. With reference to FIG. 4C and FIG. 4D, in an embodiment of block 308 and after formation of the source/drain features 408, 410, the dummy gate structures 406 are replaced with a high-K/metal gate stack. For example, the dummy gate structures 406, including the respective dummy gate electrode and dummy gate dielectric of each of the dummy gate structures 406, may initially be removed by using a suitable etching process. In some examples, the dummy gate electrode and dummy gate dielectric of each of the dummy gate structures 406 may be removed using an appropriate etching process such as a wet etch, a dry etch, or a combination thereof. In some cases, for instance in embodiments where GAA transistors are formed, a channel release process may be performed after removal of the dummy gate structures 406 to remove dummy epitaxial layers (e.g., SiGe layers) disposed between channel epitaxial layers (e.g., Si layers). After removing the dummy gate structures 406, and in a further embodiment of block 308, high-K/metal gate stacks 412 are formed in substrate regions previously occupied by the dummy gate structures 406. In some embodiments, the high-K/metal gate stacks 412 include an interfacial layer (IL) and a high-K dielectric layer 414 formed over the IL. High-K gate dielectrics, as used and described herein, include dielectric materials having a high dielectric constant, for example, greater than that of thermal silicon oxide (˜3.9).

In some embodiments, the IL may include a dielectric material such as silicon oxide (SiO₂), HfSiO, or silicon oxynitride (SiON). In some examples, the high-K dielectric layer 414 may include hafnium oxide (HfO₂). Alternatively, the high-K dielectric layer 414 may include other high-K dielectrics, such as TiO₂, HfZrO, Ta₂O₃, HfSiO₄, ZrO₂, ZrSiO₂, LaO, AlO, ZrO, TiO, Ta₂O₅, Y₂O₃, SrTiO₃ (STO), BaTiO₃ (BTO), BaZrO, HfZrO, HfLaO, HfSiO, LaSiO, AlSiO, HfTaO, HfTiO, (Ba,Sr)TiO₃ (BST), Al₂O₃, Si₃N₄, oxynitrides (SiON), combinations thereof, or other suitable material. In various embodiments, the IL and the high-K dielectric layer 414 may be formed by thermal oxidation, ALD, physical vapor deposition (PVD), pulsed laser deposition (PLD), CVD, and/or other suitable methods.

In a further embodiment of block 308, the high-K/metal gate stacks 412 further include a metal gate including a metal layer 416 is formed over the gate dielectric (e.g., over the IL and the high-K dielectric layer 414). The metal layer 416 may include a metal, metal alloy, or metal silicide. Additionally, the formation of the gate dielectric/metal gate stack may include depositions to form various gate materials, one or more liner layers, and one or more CMP processes. In some embodiments, the metal layer 416 may include a single layer or alternatively a multi-layer structure, such as various combinations of a metal layer with a selected work function to enhance the device performance (work function metal layer), a liner layer, a wetting layer, an adhesion layer, a metal alloy or a metal silicide. By way of example, the metal layer 416 may include Ti, Ag, Al, TiAlN, TaC, TaCN, TaSiN, Mn, Zr, TiN, TaN, Ru, Mo, Al, WN, Cu, W, Re, Ir, Co, Ni, other suitable metal materials or a combination thereof. In various embodiments, the metal layer 416 may be formed by ALD, PVD, CVD, e-beam evaporation, or other suitable process. Further, the metal layer 416 may be formed separately for N-type and P-type transistors which may use different metal layers. In addition, the metal layer 416 may provide an N-type or P-type work function, may serve as a transistor gate electrode, and in at least some embodiments, the metal layer 416 may include a polysilicon layer.

After formation of the high-K/metal gate stacks 412, and as illustrated in the top-down view of FIG. 4D, the high-K/metal gate stacks 412, the source/drain features 408, 410, and the active regions 402, 404 maintain symmetric patterns, in both the X-direction and the Y-direction. Stated another way, the process environment remains symmetric after formation of the high-K/metal gate stacks 412. In the present example, the symmetric process environment, as shown in the top-down view of FIG. 4D, includes the first array of repeating shapes (composed of the active regions 402, 404), the third array of repeating shapes (composed of the source/drain features 408, 410), and a fourth array of repeating shapes (composed of the high-K/metal gate stacks 412). Moreover, due to the metal stiffness of metal layer 416, potential wafer deformation caused by a subsequent patterning process (e.g., such as a CMODE patterning process) can be avoided.

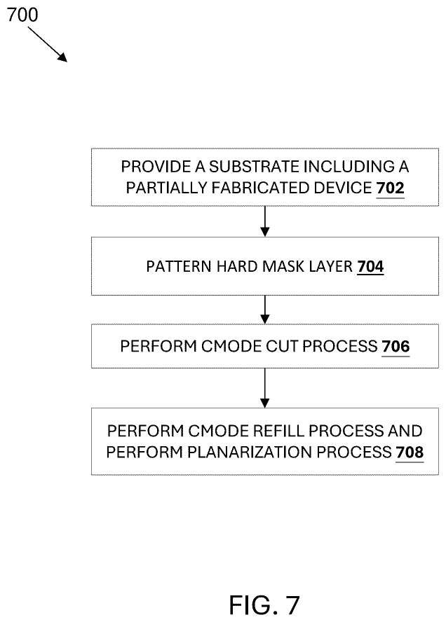

The method 300 proceeds to block 310 where a CMODE patterning process is performed. With reference to FIG. 4D and FIG. 4E, in an embodiment of block 310 and after the replacement gate process of block 308, the high-K/metal gate stacks 412 are patterned to define circuit patterns for the memory device 400 (e.g., such as circuit patterns to define an SRAM circuit). In particular, the metal layer 416 of the high-K/metal gate stacks is cut/patterned to define the circuit patterns. For example, as part of the CMODE patterning process, isolation structures 420 are formed. Generally, in various embodiments, the CMODE patterning process includes forming a trench through portions of the high-K/metal gate stacks 412, the trenches extending into the underlying substrate. Thereafter, the trenches are filled with one or more dielectric materials (e.g., including a low-K dielectric material, in some embodiments) to form the isolation structures 420, thereby providing isolation between adjacent portions of metal layer 416 for respective ones of the high-K/metal gate stacks 412. In some embodiments, the CMODE patterning process may be performed as part of middle-end-of-line (MEOL) processing. A more detailed process flow for the CMODE patterning process is described below with reference to the method of FIG. 7. As also described in more detail below, the isolation structures 420 may extend deeper into the underlying substrate than STI features that are used to separate adjacent active regions 402, 404. Due to the symmetric process environment, and due to the metal stiffness of the metal layer 416 that is present prior to the CMODE patterning process, potential wafer deformation (e.g., such as metal gate tilting) can be mitigated.

In some embodiments, the isolation structures 420 formed by the CMODE patterning process provide a much larger distance between the adjacent portions of the metal layer 416 for respective ones of the high-K/metal gate stacks 412 (e.g., such as compared to isolation structures formed using CMG patterning), thereby reducing parasitic capacitance. As shown in the example of FIG. 4E, the isolation structures 420 extend a distance D1 in the Y-direction, which is the same direction in which the high-K/metal gate stacks 412 extend. In some examples, the distance D1 is equal to or greater than a distance D2, which may be the distance that an adjacent source/drain feature (which may be the source/drain feature 410 or the source/drain feature 408, depending on where the isolation structure 420 is formed) extends in the Y-direction. Stated another way, the size of the isolation structures 420 in the Y-direction (e.g., the distance D1 that the isolation structures 420 extend in the Y-direction) is equal to or greater than the size of an adjacent source/drain feature in the Y-direction (e.g., the distance D2 that the adjacent source/drain feature extends in the Y-direction). Since capacitance is inversely proportional to distance between metal layers, the increased distance D1 provided by the isolation structures 420 will provide reduced parasitic capacitance between portions of the metal layer 416 disposed on either side of the isolation structures 420 (e.g., in the Y-direction). It is also noted that, in some embodiments, the isolation structures 420 may have a width W2 that is substantially equal to a width of the high-K/metal gate stacks 412. The width of the high-K/metal gate stacks 412, in some embodiments, may also include a width of spacers formed on sidewalls (sidewall spacers) of the high-K/metal gate stacks 412. In an example, the width W2 may be in a range of between about 10-20 nm. In some alternative embodiments, the width of the isolation structures 420 is not equal to the width of the high-K/metal gate stacks 412. For instance, as a result of at least some sidewall spacer loss that may occur during etch processing, the width of the isolation structures 420 may be greater than the width of the high-K/metal gate stacks 412. By way of example, in some cases, a ratio of the width of the isolation structures 420 to the width of the high-K/metal gate stacks 412 may be in a range of between about 1.5 to 2.5.

After the CMODE patterning process of block 310, different portions of a circuit (e.g., such as an SRAM circuit) are defined. For example, as shown in FIG. 4E, inverters 422 may be defined. Each inverter 422 includes a pull-up (PU) transistor 424 and a pull-down (PD) transistor 426, similar to inverter 210 (composed of PU-1, PD-1) and inverter 220 (composed of PU-2, PD-2), described above with reference to FIG. 2. The PU transistor 424 is configured as a P-type transistor (e.g., such as a FinFET or GAA transistor), and the PD transistor 426 is configured as an N-type transistor (e.g., such as a FinFET or GAA transistor). In particular, the PU transistor 424 is formed by source/drain features 410 formed within the P-type device region 405 over an active region 404 and on either side of a high-K/metal gate stack 412. Similarly, the PD transistor 426 is formed by source/drain features 408 formed within an N-type device region 403 over an active region 402 and on either side of the high-K/metal gate stack 412. In addition, and still with reference to FIG. 4E, pass-gate (PG) transistors 428 may be defined. The PG transistors 428 are similar to PG-1, PG-2, described above with reference to FIG. 2. Each PG transistor 428 is configured as an N-type transistor (e.g., such as a FinFET or GAA transistor). In particular, the PG transistor 428 is formed by source/drain features 408 formed within an N-type device region 403 over an active region 402 and on either side of the high-K/metal gate stack 412. While the example of FIG. 4E illustrates the PG transistors 428 formed in N-type device regions 403 having single active regions 402, other embodiments are possible. For example, if the N-type device regions 403 instead had two active regions 402, portions of the high-K/metal gate stack between the two active regions 402 may be separated using a CMODE/CPODE patterning process or a CMG patterning process. A similar procedure may be used for PG transistors formed in the P-type device region 405, in some embodiments. In addition, and in some embodiments, if N-type transistors are used for the PG transistors, P-type PG transistors may be disabled/electrically isolated using a CMODE/CPODE patterning process, and vice versa if P-type transistors are used for the PG transistors.

The method 300 proceeds to block 312 where further processing is performed. For example, in an embodiment of block 312, back-end-of-line (BEOL) routing may be performed. BEOL routing may include formation of various conductive features to interconnect various portions of a circuit (e.g., such as various portions of an SRAM circuit) that were previously patterned/defined by the CMODE patterning process, as described above. In particular, BEOL routing may include formation of a multilevel interconnect (MLI) structure that includes various conductive features, which may be vertical interconnects, such as contacts and/or vias, and/or horizontal interconnects, such as conductive lines. In some embodiments, the BEOL routing may be used to connect inverters 422 and PG transistors 428 to in a manner as shown and described with reference to FIG. 2, to define an SRAM cell. Considering the array of N-type and P-type transistors provided in the memory device 400, and as illustrated in FIG. 4E, it is thus evident that the memory device 400 may be composed of a plurality of SRAM cells. Further, it will be understood that in some embodiments, certain ones of the source/drain features may be shared between adjacent transistors. Also, while the exemplary SRAM described above is shown and described as being a 6T SRAM, other embodiments are possible. Generally, in various embodiments, different numbers of inverters (e.g., such as the inverters 422) may be formed, with or without pass-gate transistors, to form other types of memory devices (e.g., such as 4T SRAM, 8T SRAM, etc.), as well as other types of logic devices and/or logic circuits.

As previously noted, the memory device 400 may be implemented using various types of multi-gate devices, such as FinFETs, GAA transistors (or nanosheet transistors), other types of advanced transistor devices. As also discussed, when FinFETs are to be used to fabricate the memory device 400, the active regions 402, 404 may include fins (composed of a substantially uniform composition) extending from a substrate, and when GAA transistors (or nanosheet transistors) are to be used to fabricate the memory device 400, the active regions 402, 404 may include a plurality of stacked channel layers (or a plurality of stacked nanosheets) that are stacked over the substrate and which form the channels of the GAA transistor.

Elaborating on this discussion, and in various embodiments, SRAM operation margin and performance may be degraded due to a mismatch between N-type and P-type transistors used as pull-down transistors (N-type), pull-up transistors (P-type), and pass-gate transistors (N-type). Such mismatch may occur, in some cases, due to the difference between electron and hole mobility. Thus, in some embodiments and to enhance SRAM operation margin and performance, it may be desirable to match N-type and P-type transistors by sizing the transistors based on the mobility ratio between the N-type and P-type transistors. Depending on whether FinFETs or GAA transistors are to be used to fabricate the memory device 400, the N-type and P-type transistor matching may be performed differently.

Considering an example where FinFETs are to be used to fabricate the memory device 400, and prior to N/P matching as in the example of FIG. 4E, each of the N-type and P-type transistors includes a single fin (e.g., single active regions 402, 404 for each transistor). To provide N/P matching, if the mobility ratio of the N-type and P-type transistors is equal to about X:Y, the area ratio of N-type fins and P-type fins may be adjusted to be equal to about Y:X. As merely one example, if the mobility ratio of the N-type and P-type transistors is equal to about 3:2, the arca ratio of N-type fins and P-type fins may be adjusted to be equal to about 2:3 to provide N/P matching. For the case of FinFETs, such area ratio adjustments may be accomplished by varying the number of fins (the number of active regions) used to implement respective N-type and P-type transistors. Thus, for instance, with the mobility ratio of the N-type and P-type transistors equal to about 3:2, N-type transistors (e.g., for pull-down and pass-gate transistors) may be implemented using two fins (two parallel active regions 402 with a single high-K/metal gate stack 412 and single source/drain features 408 on either side of the single high-K/metal gate stack 412 that merge across the multiple fins), and the P-type transistors (e.g., for pull-up transistors) may be implemented using three fins (three parallel active regions 404 with a single high-K/metal gate stack 412 and single source/drain features 410 on either side of the single high-K/metal gate stack 412 that merge across the multiple fins), to provide N/P matching by ensuring that the N/P area ratio is 2:3.

Considering an example where GAA transistors are to be used to fabricate the memory device 400, and prior to N/P matching as in the example of FIG. 4E, each of the N-type and P-type transistors includes stacked nanosheets having a width W1 (e.g., active regions 402, 404 having a width W1). To provide N/P matching, if the mobility ratio of the N-type and P-type transistors is equal to about X:Y, the area ratio of the nanosheets for the N-type and P-type devices may be adjusted to be equal to about Y:X. As merely one example, if the mobility ratio of the N-type and P-type transistors is equal to about 3:2, the area ratio of the nanosheets for the N-type and P-type devices may be adjusted to be equal to about 2:3 to provide N/P matching. For the case of GAA transistors, such area ratio adjustments may be accomplished by varying the width W1 of the stacked nanosheets used to implement respective N-type and P-type transistors. Thus, for instance, with the mobility ratio of the N-type and P-type transistors equal to about 3:2, N-type transistors (e.g., for pull-down and pass-gate transistors) and P-type transistors may be implemented using nanosheets having a ratio of widths of the stacked nanosheets equal to about 2:3 to provide N/P matching.

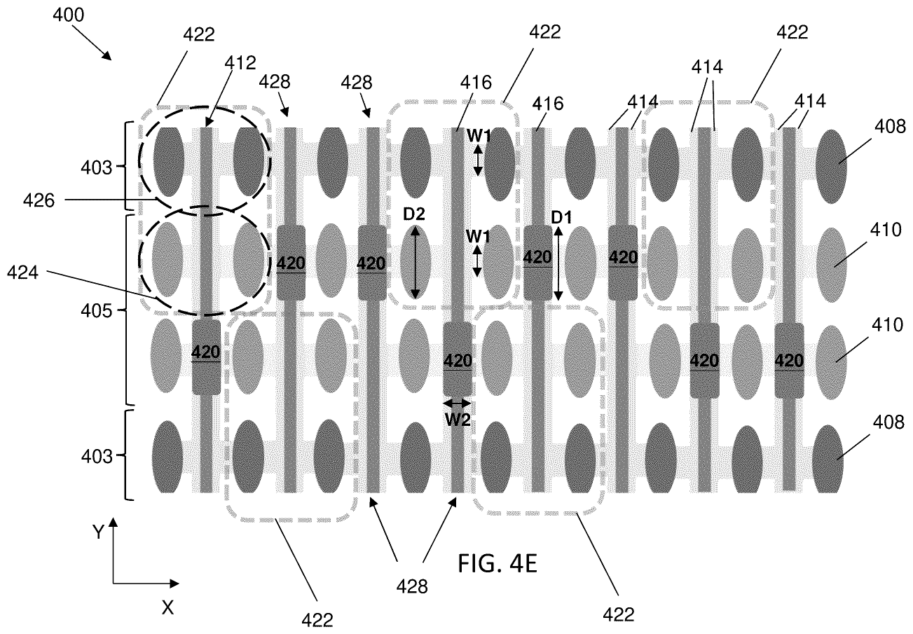

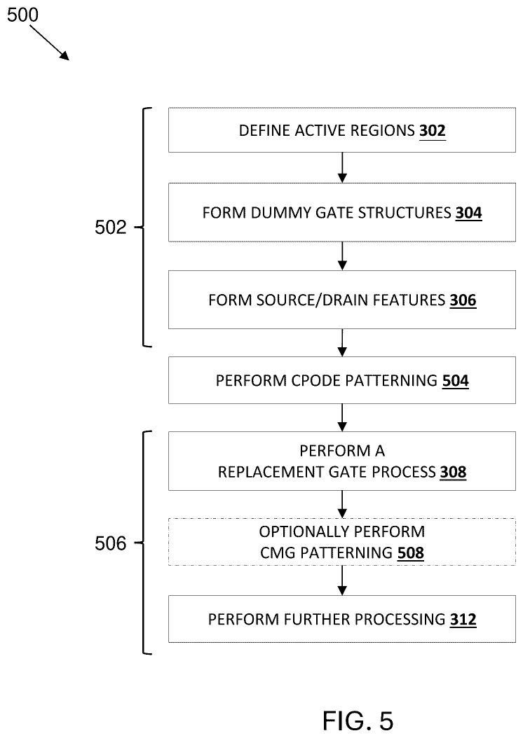

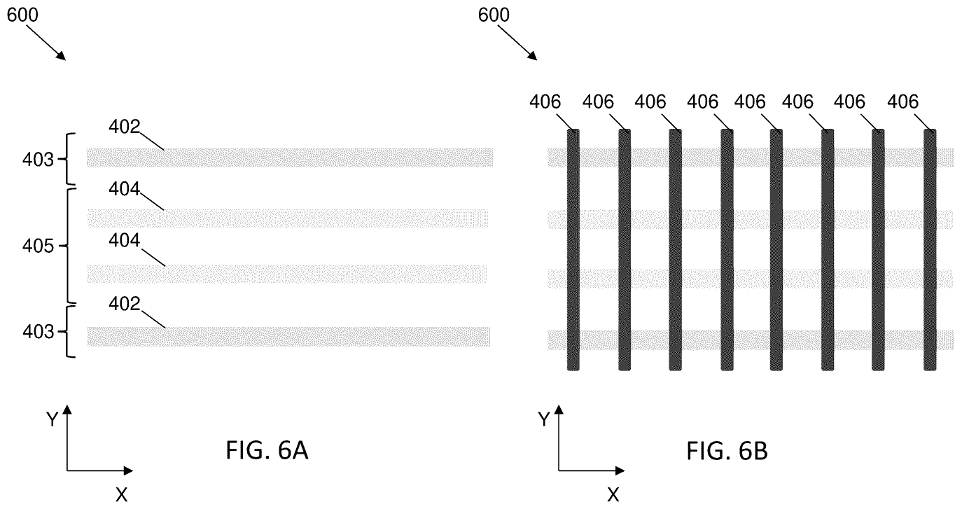

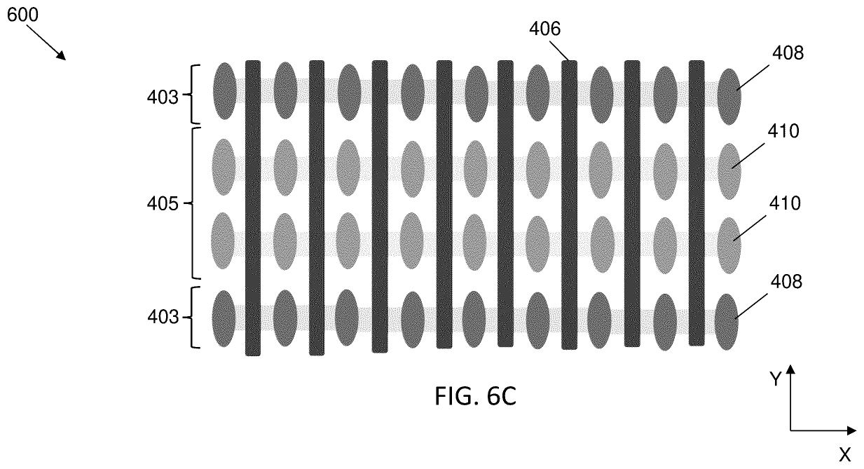

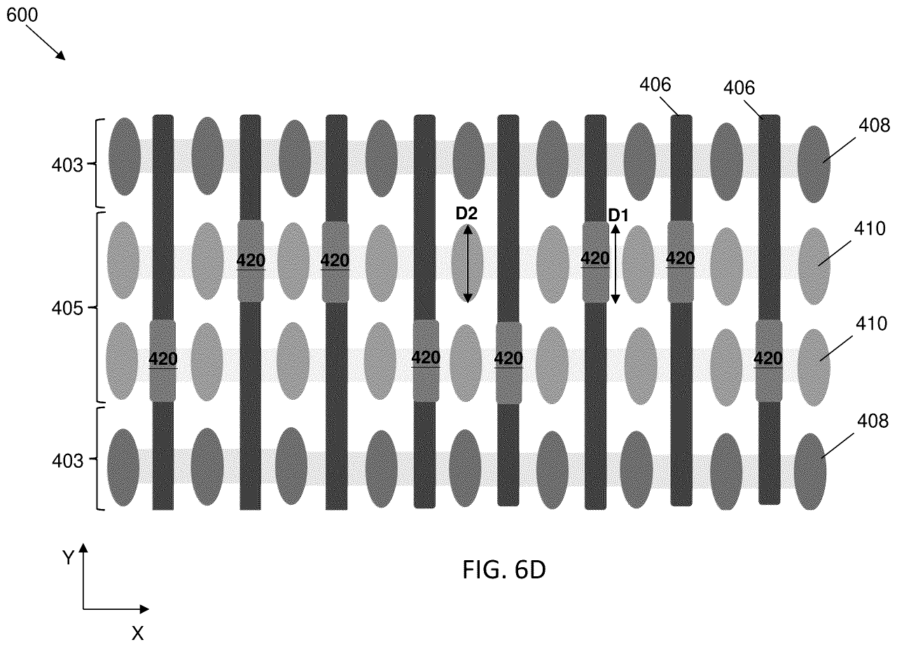

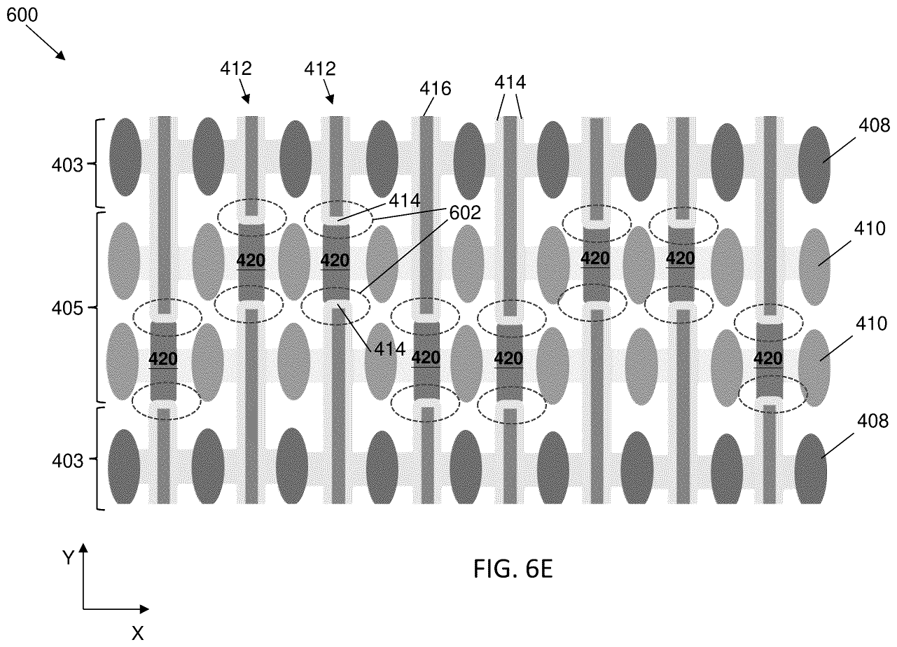

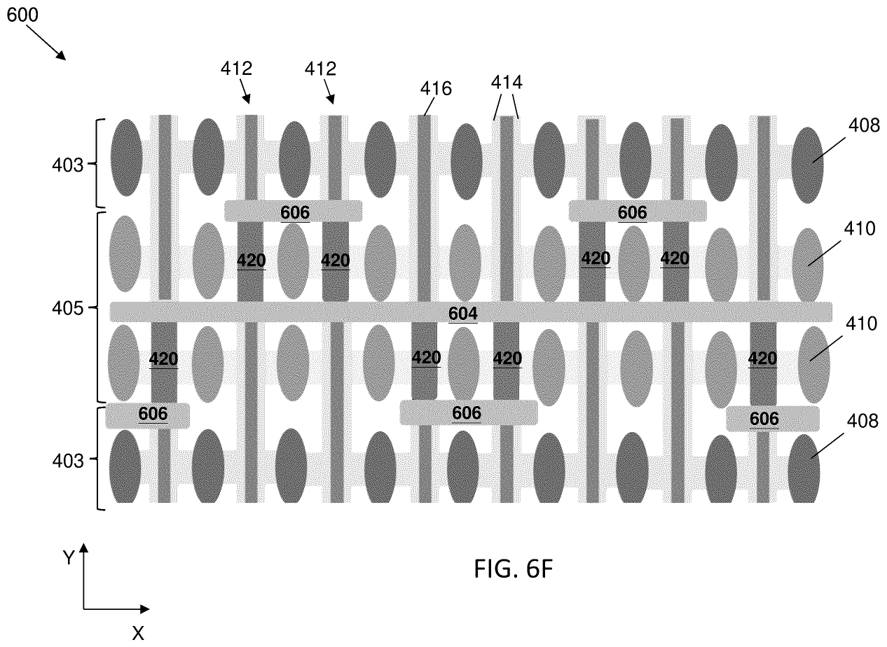

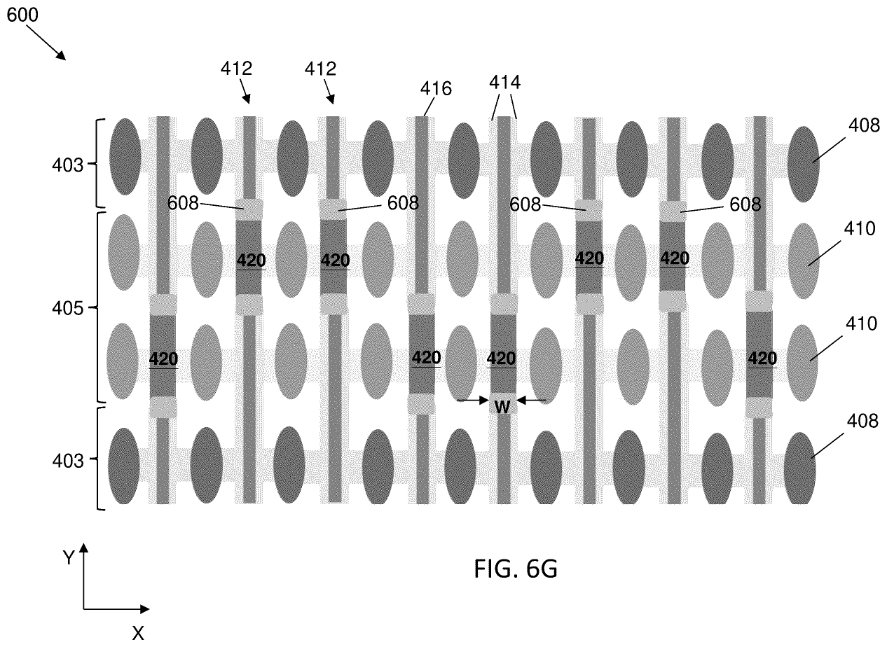

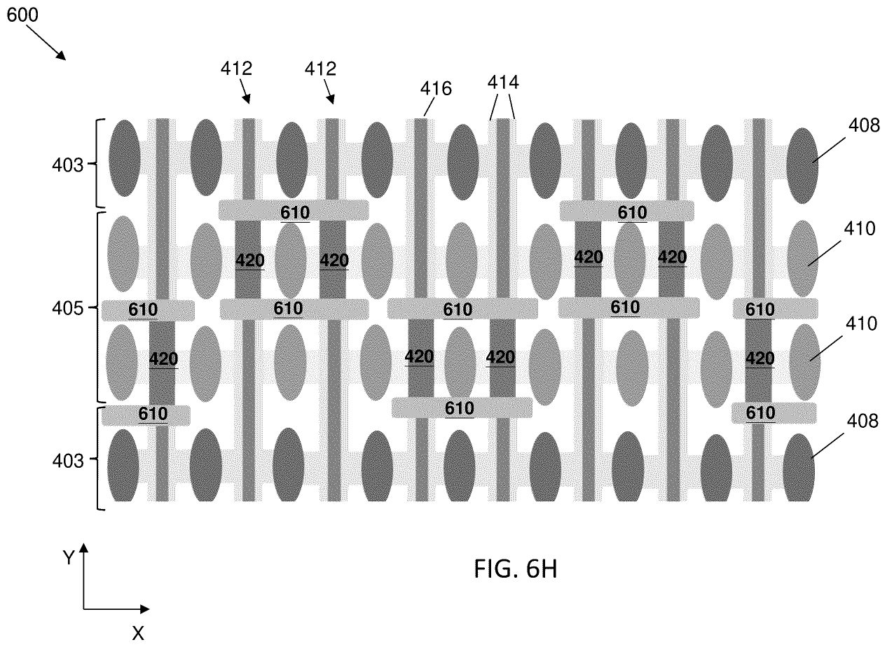

With reference to FIG. 5, illustrated therein is a method 500 of semiconductor fabrication including fabrication of a memory device 600 (e.g., which includes an SRAM circuit) using a CPODE patterning process, in accordance with various embodiments. The method 500 is described below with reference to FIGS. 6A-6H, which provide top-down views of an embodiment of the memory device 600 at various stages of fabrication according to the method 500. It will be understood that aspects of the method 500 may be applied to devices or circuits implemented using various types of multi-gate devices, such as FinFETs, GAA transistors (or nanosheet transistors), other types of advanced transistor devices, or combinations thereof, without departing from the scope of the present disclosure. In some embodiments, the method 500 may be used to fabricate the multi-gate device 100 described above with reference to FIG. 1 or the SRAM cell 200 described above with reference to FIG. 2. Thus, one or more aspects discussed above with reference to the multi-gate device 100, or with reference to the SRAM cell 200, may also apply to the method 500 and to the memory device 600. It is understood that the method 500 includes steps having features of a CMOS technology process flow and thus, are only described briefly herein. Also, additional steps may be performed before, after, and/or during the method 500.

It is further noted that, in some embodiments, the memory device 600 may include various other devices and features, such as other types of devices such as additional transistors, bipolar junction transistors, resistors, capacitors, inductors, diodes, fuses and/or other logic circuits, etc., but is simplified for a better understanding of the inventive concepts of the present disclosure. In some embodiments, the memory device 600 may include a plurality of semiconductor devices (e.g., transistors) which may be interconnected to form a circuit, such as an SRAM circuit. Moreover, it is noted that the process steps of method 500, including any descriptions given with reference to the figures are merely exemplary and are not intended to be limiting beyond what is specifically recited in the claims that follow. Further, the method 500 is similar to the method 300, discussed above, in various respects. Thus, some aspects of the method 500 which have previously been described during the discussion of the method 300 are only briefly described below. In addition, and for clarity of discussion, reference numerals used in the discussion of the method 300 may be repeated below in the discussion of the method 500.

The method 500 begins by performing a sequence of steps 502. The sequence of steps 502 may include blocks 302, 304, and 306 of the method 300, discussed above. Thus, with reference to FIG. 6A, in an embodiment of block 302 of the sequence of steps 502, active regions 402 and active regions 404 are initially defined, as discussed above with reference to the method 300. In the top-down view of FIG. 6A, as in the top-down view of FIG. 4A (which corresponds to block 302 of the method 300), the symmetric process environment includes an array of repeating shapes (or a repeating pattern) composed of the active regions 402, 404. Next, with reference to FIG. 6B, in an embodiment of block 304 of the sequence of steps 502, a plurality of dummy gate structures 406 are formed over the active regions 402, 404, as discussed above with reference to the method 300. As previously discussed, and due to the symmetric process environment provided by the symmetric patterns of the active regions 402, 404 over which the dummy gate structures 406 are formed, the dummy gate structures 406 will have a good polysilicon LER. In the top-down view of FIG. 6B, as in the top-down view of FIG. 4B (which corresponds to block 304 of the method 300), the symmetric process environment includes a first array of repeating shapes (composed of the active regions 402, 404) and a second array of repeating shapes (composed of the dummy gate structures 406). Thereafter, with reference to FIG. 6C, in an embodiment of block 306 of the sequence of steps 502, source/drain features 408, 410 are formed in the source/drain regions adjacent to and on either side of the dummy gate structures 406 within the N-type device regions 403 and the P-type device region 405, respectively, as discussed above with reference to the method 300. As previously discussed, and due to the symmetric process environment provided by the symmetric patterns of the dummy gate structures 406 and the active regions 402, 404, formation of the source/drain features 408, 410 can be performed with minimal loss of stress applied by the source/drain features 408, 410 onto the channel regions of respective ones of the N-type transistors and the P-type transistors. In the top-down view of FIG. 6C, as in the top-down view of FIG. 4C (which corresponds to block 306 of the method 300), the symmetric process environment includes the first array of repeating shapes (composed of the active regions 402, 404), the second array of repeating shapes (composed of the dummy gate structures 406), and a third array of repeating shapes (composed of the source/drain features 408, 410). Thus, after the sequence of steps 502 of the method 500 (FIG. 6C), the memory device 600 looks substantially the same as the memory device 400 after block 306 of the method 300 (FIG. 4C).

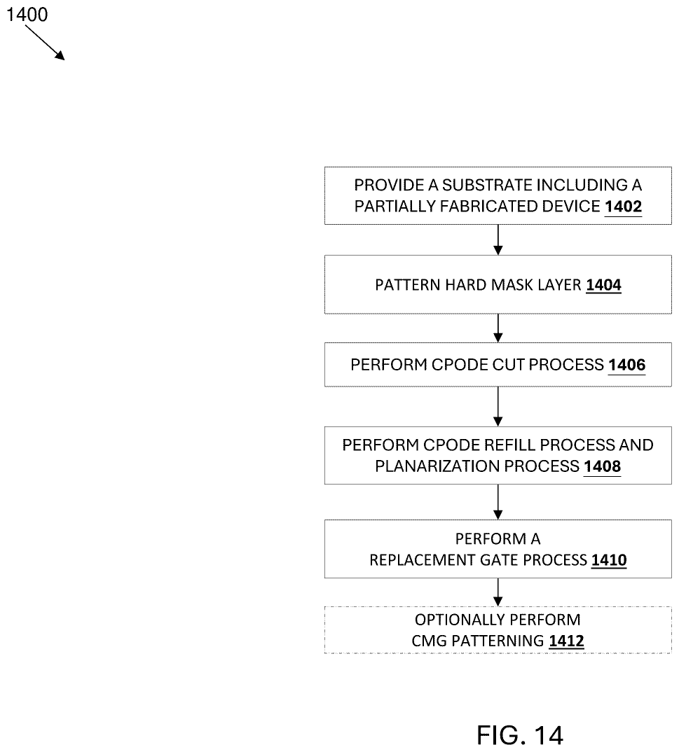

After the sequence of steps 502, rather than next performing a replacement gate process as in the method 300, the method 500 proceeds to block 504 where a CPODE patterning process is performed. With reference to FIG. 6C and FIG. 6D, in an embodiment of block 504 and after formation of the source/drain features 408, 410, the dummy gate structures 406 are patterned to define circuit patterns for the memory device 600 (e.g., such as circuit patterns to define an SRAM circuit). For example, as part of the CPODE patterning process, isolation structures 420 are formed. In various embodiments, the isolation structures 420 may be substantially the same as discussed above with reference to the method 300. However, the isolation structures 420 are formed at a different stage of processing in the method 500 (CPODE patterning process) as compared to the method 300 (CMODE patterning process). Generally, by way of example, the CPODE patterning process includes forming a trench through portions of the dummy gate structures 406, the trenches extending into the underlying substrate. Thereafter, the trenches are filled with one or more dielectric materials to form the isolation structures 420, thereby providing isolation between adjacent portions of respective dummy gate structures 406, which are replaced at a later stage of processing by a high-K/metal gate stack. In some embodiments, the CPODE patterning process may be performed as part of MEOL processing. A more detailed process flow for the CPODE patterning process is described below with reference to the method of FIG. 14. In some cases, and because the isolation structures 420 are formed prior to the replacement gate process, there may be a risk of potential wafer deformation (e.g., such as metal gate tilting).

In some embodiments, the isolation structures 420 formed by the CPODE patterning process provide an increased distance between the adjacent portions of respective dummy gate structures 406 (and thus provide for an increased distance between portions of the metal layer 416 for respective high-K/metal gate stacks 412 that replace the dummy gate structures 406 at a later stage of processing), such as compared to isolation structures formed using CMG patterning, thereby reducing parasitic capacitance. As shown in the example of FIG. 6D, and as discussed above with reference to the method 300, the isolation structures 420 extend a distance D1 in the Y-direction, which is the same direction in which the dummy gate structures 406 extend. As also previously noted, the size of the isolation structures 420 in the Y-direction (e.g., the distance D1 that the isolation structures 420 extend in the Y-direction) is equal to or greater than the size of an adjacent source/drain feature in the Y-direction (e.g., the distance D2 that the adjacent source/drain feature extends in the Y-direction). Since capacitance is inversely proportional to distance between metal layers, the increased distance D1 provided by the isolation structures 420 may provide reduced parasitic capacitance between portions of the metal layer 416, formed during subsequent processing, and disposed on either side of the isolation structures 420 (e.g., in the Y-direction). However, since the replacement gate process is performed after formation of the isolation structures 420 in the method 500 (CPODE patterning process), there may be some undesirable metal boundary effects, as discussed below.

After performing the CPODE patterning process, the method 500 proceeds to performing a sequence of steps 506. The sequence of steps 506 may include blocks 308 and 312 of the method 300, discussed above. The sequence of steps 506 also optionally includes block 508, performed after block 308 and before block 312, as described in more detail below. Thus, with reference to FIG. 6D and FIG. 6E, in an embodiment of block 308 of the sequence of steps 506, a replacement gate process is initially performed to replace the dummy gate structures 406 with a high-K/metal gate stack, in a similar manner as discussed above with reference to the method 300. For example, the dummy gate structures 406 may be replaced by high-K/metal gate stacks 412 formed in substrate regions previously occupied by the dummy gate structures 406. As previously described, the high-K/metal gate stacks 412 include an IL, a high-K dielectric layer 414 formed over the IL, and a metal gate including a metal layer 416 formed over the gate dielectric (e.g., over the IL and the high-K dielectric layer 414).

As shown in the top-down view of FIG. 6E, the high-K/metal gate stacks 412 and the isolation structures 420 interface (or contact) each other along opposite sides of respective ones of the isolation structures 420 within regions 602. In particular, since the dummy gate structures 406 are replaced by the high-K/metal gate stacks 412 after formation of the isolation structures 420, the high-K dielectric layer 414 wraps around a metal line end region of the metal layer 416 such that the high-K dielectric layer 414 is disposed along an entirety of the interface between the high-K/metal gate stacks 412 and the isolation structures 420. In some embodiments, the portions of the high-K dielectric layer 414 disposed along the entirety of the interface between the high-K/metal gate stacks 412 and the isolation structures 420 may result in increased metal boundary effects (MBEs), which for example, may include increased parasitic capacitance between portions of the metal layer 416 disposed on opposite sides of a respective isolation structure 420. Such MBEs may be mitigated by the use of an optional CMG patterning process, as described with reference to FIGS. 6F-6H.

If the optional CMG patterning process is to be performed, the method proceeds to block 508 of the sequence of steps 506. With reference to FIG. 6E and FIGS. 6F-6H, in an embodiment of block 508, a CMG patterning process is used to remove the portions of the high-K dielectric layer 414 disposed within regions 602, to reduce parasitic capacitance. By way of example, the CMG patterning process may include forming a cut metal gate trench through a portion of the high-K/metal gate stacks 412 in the regions 602. Formation of the cut metal gate trench removes the portions of the high-K dielectric layer 414 disposed along the entirety of the interface between the high-K/metal gate stacks 412 and the isolation structures 420 within the regions 602. Thereafter, the cut metal gate trench is refilled with a dielectric material (e.g., including a low-K dielectric material, in some embodiments) to form a cut metal gate (CMG) isolation structure. As a result, MBE-induced parasitic capacitance can be effectively mitigated. Depending on the particular application and scaling limits imposed in advanced processing nodes, different embodiments of the CMG patterning process may be implemented.

For example, in a first embodiment and with reference to the example of FIG. 6F, a first elongated CMG isolation structure 604 and a plurality of second elongated CMG isolation structures 606 may be formed. As shown, the first elongated CMG isolation structure 604 is longer than the second elongated CMG isolation structures 606. In addition, each of the first and second elongated CMG isolation structures 604, 606 extend along the X-direction, perpendicular to the isolation structures 420 and the high-K/metal gate stacks 412, which both extend along the Y-direction. In the illustrated embodiment, the first elongated CMG isolation structure 604 extends through eight (8) different regions 602 corresponding to eight (8) different isolation structures 420, thereby removing the portions of the high-K dielectric layer 414 disposed on one side of each of the eight (8) different isolation structures 420. In addition, a plurality of source/drain features 410, corresponding to various different transistors of the memory device 600, are disposed on either side of the first elongated CMG isolation structure 604. The second elongated CMG isolation structures 606 each extend through one (1) or two (2) different regions 602 corresponding to one (1) or two (2) different isolation structures 420. Each of the plurality of second elongated CMG isolation structures 606 serves to remove portions of the high-K dielectric layer 414 disposed on one side of one (1) or two (2) different isolation structures 420. Additionally, at least a pair of source/drain features 408,410 are disposed on either side of, or adjacent to, each of the second elongated CMG isolation structures 606. Thus, by a combination of the first and second elongated CMG isolation structures 604, 606, each of the isolation structures 420 will have portions of the high-K dielectric layer 414 disposed within regions 602 on either side of respective ones of the isolation structures 420, removed and replaced by a CMG dielectric material to reduce parasitic capacitance.

In a second embodiment and with reference to the example of FIG. 6G, a plurality of CMG isolation structures 608, where the CMG isolation structures 608 are via structures, may be formed. As shown, each of the CMG isolation structures 608 may be similarly sized and may have a width W that is substantially equal to that of the high-K/metal gate stacks 412. In the illustrated embodiment, CMG isolation structures 608 are formed on opposite sides of each of the isolation structures 420 in regions 602, thereby removing the portions of the high-K dielectric layer 414 disposed on each side of the isolation structures 420. Stated another way, each of the isolation structures 420 will have portions of the high-K dielectric layer 414 disposed within regions 602 on either side of respective ones of the isolation structures 420, removed and replaced by a CMG dielectric material to reduce parasitic capacitance. Additionally, because the CMG isolation structures 608 do not extend beyond a width of the high-K/metal gate stacks 412 and are thus not adjacent to any of the source/drain features 408, 410, there is a reduced chance of damage to the source/drain features 408, 410 by the CMG patterning process.

In a third embodiment and with reference to the example of FIG. 6H, a plurality of elongated CMG isolation structures 610 may be formed. In some embodiments, the plurality of elongated CMG isolation structures 610 may be similar to the second elongated CMG isolation structures 606, discussed above. Moreover, the example of FIG. 6H may be similar to the example of FIG. 6F, discussed above. However, in the example of FIG. 6H, the first elongated CMG isolation structure 604 (FIG. 6F) is effectively replaced by a plurality of shorter CMG isolation structures 610 (which may be the second elongated CMG isolation structures 606). By using the configuration of FIG. 6H, proximity effects can be reduced. It is noted that due to the scaling limits imposed in advanced processing nodes, there may not be sufficient space to perform the optional CMG patterning process and form respective CMG isolation structures, in some cases.

After the replacement gate process (block 308), or after the optional CMG patterning process (block 508), the method 500 proceeds to block 312 of the sequence of steps 506, where further processing (e.g., such as BEOL routing) is performed. Like the memory device 400, the memory device 600 will also include various inverters (e.g., similar to the inverters 422) and PG transistors (e.g., similar to the PG transistors 428) that were patterned/defined by the CPODE patterning process and completed by the replacement gate process, as described above. The BEOL routing may include formation of various conductive features to interconnect various portions of the circuit (e.g., such as inverters and PG transistors) that were previously defined. As previously described, BEOL routing may include formation of a MLI structure that includes various conductive features, which may be vertical interconnects, such as contacts and/or vias, and/or horizontal interconnects, such as conductive lines. The BEOL routing may be used to connect the inverters and PG transistors of the memory device 600, in a manner as shown and described with reference to FIG. 2, to define a plurality of SRAM cells.

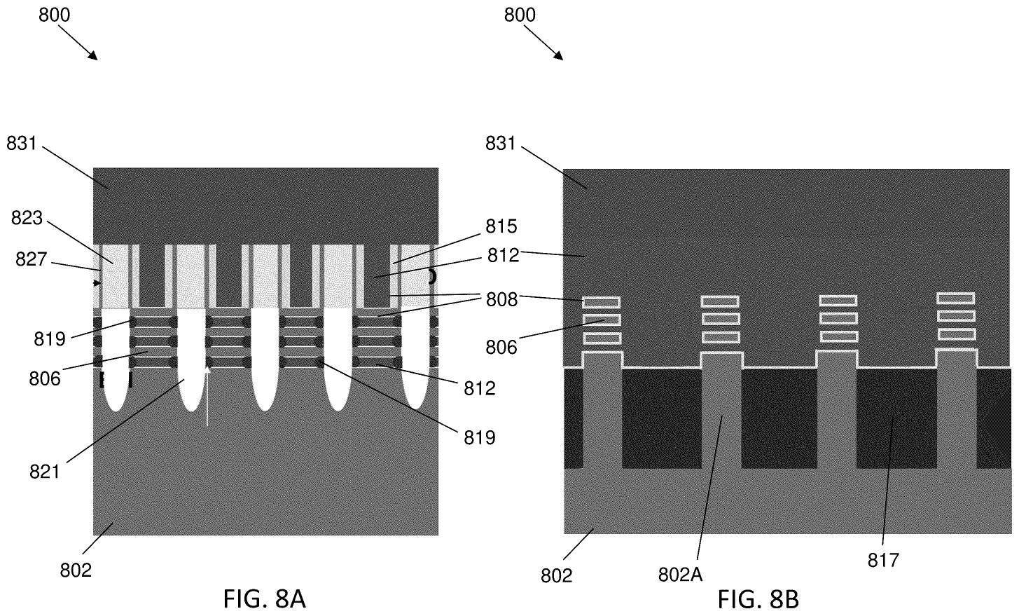

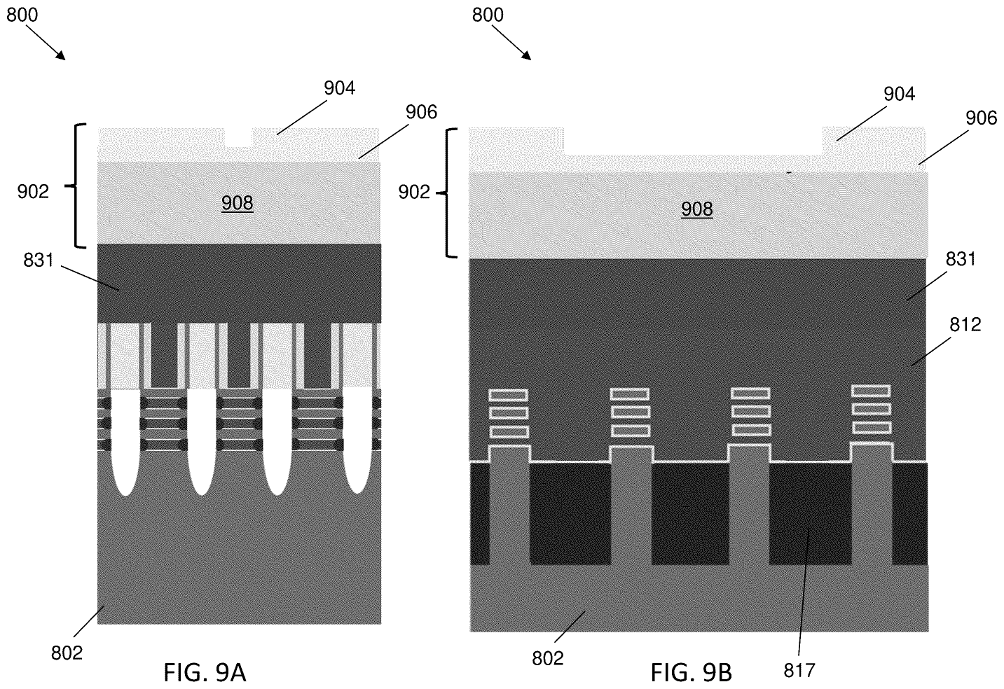

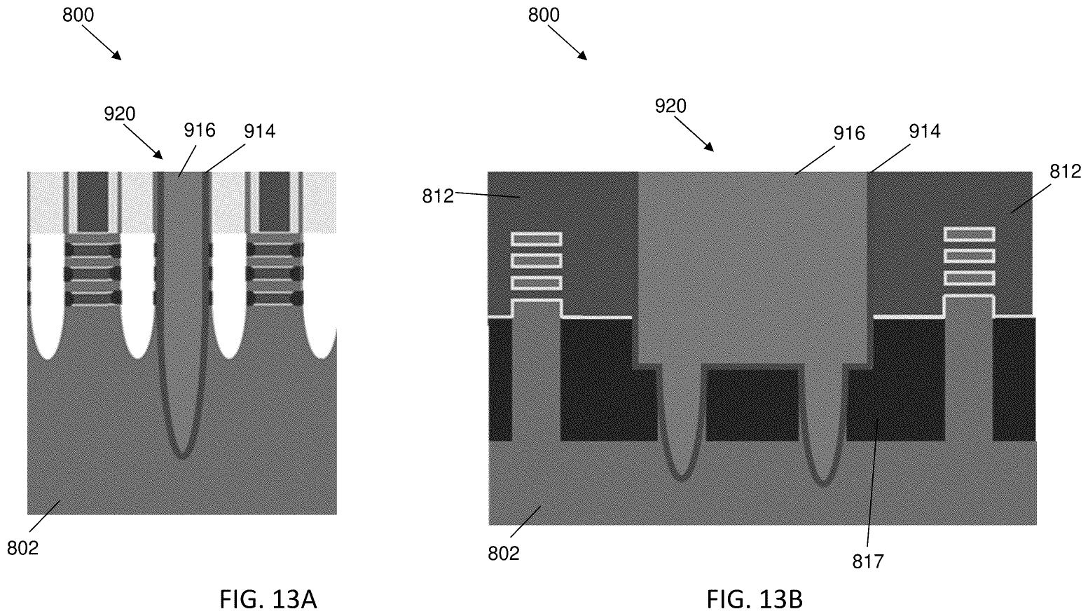

Referring now to FIG. 7, illustrated therein is a method 700 of fabricating a semiconductor device 800 using a CMODE patterning process, in accordance with various embodiments. In some embodiments, the method 700 provides the CMODE patterning process, discussed above with reference to block 310 of the method 300. The method 700 is discussed below with reference to a semiconductor device including a GAA transistor. However, it will be understood that aspects of the method 700 may be equally applied to other types of multi-gate devices such as FinFETs, as discussed above, without departing from the scope of the present disclosure. The method 700 is described below with reference to FIGS. 8A/8B-13A/13B, which provide cross-sectional views of the semiconductor device 800 at various stages of fabrication according to the method 700. In particular, FIGS. 8A-13A provide cross-sectional views of an embodiment of the semiconductor device 800 along a plane substantially parallel to a plane defined by section AA′ of FIG. 1. In addition, FIGS. 8B-13B provide cross-sectional views of an embodiment of the semiconductor device 800 along a plane substantially parallel to a plane defined by section BB′ of FIG. 1. In some embodiments, the method 700 may be used to fabricate the multi-gate device 100 described above with reference to FIG. 1 or the SRAM cell 200 described above with reference to FIG. 2. Thus, one or more aspects discussed above with reference to the multi-gate device 100, or with reference to the SRAM cell 200, may also apply to the method 700 and to the semiconductor device 800. It is understood that the method 700 includes steps having features of a CMOS technology process flow and thus, are only described briefly herein. Also, additional steps may be performed before, after, and/or during the method 700.

The method 700 begins at block 702 where a partially fabricated multi-gate device is provided. With reference to FIGS. 8A/8B, in an embodiment of block 702, a partially fabricated semiconductor device 800 is provided. The semiconductor device 800 is formed on a substrate 802, which may be substantially the same as described above with reference to the memory device 400. The substrate 802 may include active regions having a plurality of stacked nanosheet channel layers 806 disposed over the substrate 802. The active regions may be the active regions 402, 404, discussed above, in some embodiments.

In some embodiments, the nanosheet channel layers 806 may include silicon (Si). However, in some embodiments, the nanosheet channel layers 806 may include other materials such as germanium, a compound semiconductor such as silicon carbide, gallium arsenide, gallium phosphide, indium phosphide, indium arsenide, and/or indium antimonide, an alloy semiconductor such as SiGe, GaAsP, AlInAs, AlGaAs, InGaAs, GaInP, and/or GaInAsP, or combinations thereof. By way of example, the nanosheet channel layers 806 may be epitaxially grown by a molecular beam epitaxy (MBE) process, a metalorganic chemical vapor deposition (MOCVD) process, and/or other suitable epitaxial growth processes.

In various embodiments, each of the active regions includes a substrate portion 802A formed from the substrate 802 and the plurality of stacked nanosheet channel layers 806. It is noted that while the semiconductor device 800 illustrated as including three (3) nanosheet channel layers 806, this is for illustrative purposes only and is not intended to be limiting beyond what is specifically recited in the claims. It can be appreciated that any number of nanosheet channel layers 806 can be formed, where for example, the number of nanosheet channel layers 806 depends on the desired number of channels regions for the GAA devices. In some embodiments, the number of nanosheet channel layers 806 is between 3 and 10.

Shallow trench isolation (STI) features 817 may also be formed interposing the adjacent active regions. In some embodiments, the STI features 817 include SiO₂, silicon nitride, silicon oxynitride, fluorine-doped silicate glass (FSG), a low-K dielectric, combinations thereof, and/or other suitable materials known in the art. In various examples, the dielectric layer used to form the STI features 817 may be deposited by a CVD process, a subatmospheric CVD (SACVD) process, a flowable CVD process, an ALD process, a PVD process, and/or other suitable process.

The semiconductor device 800 further includes gate structures in the form of high-K/metal gate stacks, which may be similar to the high-K/metal gate stacks 412, described above. In some embodiments, the gate structures may form the gates associated with the multi-channels provided by the nanosheet channel layers 806 in the channel region of the respective GAA devices. The gate structure may include a gate dielectric 808 including an IL and a high-K gate dielectric layer formed over the IL. In some embodiments, the gate dielectric 808 has a total thickness of about 1-5 nm. Additionally, in various embodiments, the IL and the high-K gate dielectric may include one or more of the material compositions described above, with reference to the memory device 400. In some embodiments, the gate structure may further include a metal gate having a metal layer 812 formed over the gate dielectric 808. In some cases, the metal layer 812 may be substantially the same as the metal layer 416, discussed above. In the present example, the gate structure includes portions that interpose each of the nanosheet channel layers 806, where the nanosheet channel layers 806 each provide semiconductor channel layers for respective GAA transistors. Additionally, in some examples, another metal layer (e.g., such as a selectively-grown tungsten (W) layer) may be formed over the metal layer 812. In some cases, the selectively-grown W layer may include a fluorine-free W (FFW) layer. In various examples, the selectively-grown W layer may serve as an etch-stop layer and may also provide reduced contact resistance (e.g., to the metal layer 812).

In some embodiments, a spacer layer 815 may be formed on sidewalls of a top portion of each of the gate structures. The spacer layer 815 may be formed prior to formation of the high-K/metal gate stack of the gate structure. For example, in some cases, the spacer layer 815 may be formed on sidewalls of a previously formed dummy (sacrificial) gate stack that is removed and replaced by the high-K/metal gate stack, described above, as part of a replacement gate (gate-last) process. In some examples, the spacer layer 815 may include a dielectric material such as silicon oxide, silicon nitride, silicon carbide, silicon oxynitride, SiCN, silicon oxycarbide, SiOCN, SiOHCN, a low-K material (e.g., with a dielectric constant ‘k’<7), and/or combinations thereof. In some embodiments, the spacer layer 815 includes multiple layers, such as main spacer layers, liner layers, and the like.

In some embodiments, inner spacers 819 may be disposed between adjacent channels of the nanosheet channel layers 806, at lateral ends of the nanosheet channel layers 806, and in contact with portions of the gate structure that interpose each of the nanosheet channel layers 806. In some embodiments, the inner spacers 819 include amorphous silicon. In some examples, the inner spacers 819 may include silicon oxide, silicon nitride, silicon carbide, silicon oxynitride, SiCN, silicon oxycarbide, SiOCN, a low-K material (e.g., with a dielectric constant ‘k’<7), and/or combinations thereof. In various examples, the inner spacers 819 may extend beneath the spacer layer 815, described above, while abutting adjacent source/drain features, described below.

In some embodiments, source/drain features 821 are formed in source/drain regions adjacent to and on either side of the gate structure of each of the GAA transistors. As shown, the source/drain features 821 are in contact with the inner spacers 819 and nanosheet channel layers 806 of respective GAA transistors. In various examples, the source/drain features 821 may be formed by one or more epitaxial (epi) processes, may be formed in separate processing sequences for each of N-type and P-type source/drain features, and generally may be similar to the source/drain features 408, 410, described above.

The semiconductor device 800 may further include an inter-layer dielectric (ILD) layer 823. In some embodiments, a contact etch stop layer (CESL) 827 is formed prior to forming the ILD layer 823. In some examples, the CESL 827 includes a silicon nitride layer, silicon oxide layer, a silicon oxynitride layer, and/or other materials known in the art. The CESL 827 may be formed by plasma-enhanced chemical vapor deposition (PECVD) process and/or other suitable deposition or oxidation processes. In some embodiments, the ILD layer 823 includes materials such as tetraethylorthosilicate (TEOS) oxide, un-doped silicate glass, or doped silicon oxide such as borophosphosilicate glass (BPSG), FSG, phosphosilicate glass (PSG), boron doped silicon glass (BSG), and/or other suitable dielectric materials. The ILD layer 823 may be deposited by a PECVD process or other suitable deposition technique. In some embodiments, a hard mask layer 831 (e.g., such as SiN) may be formed over the semiconductor device 800.

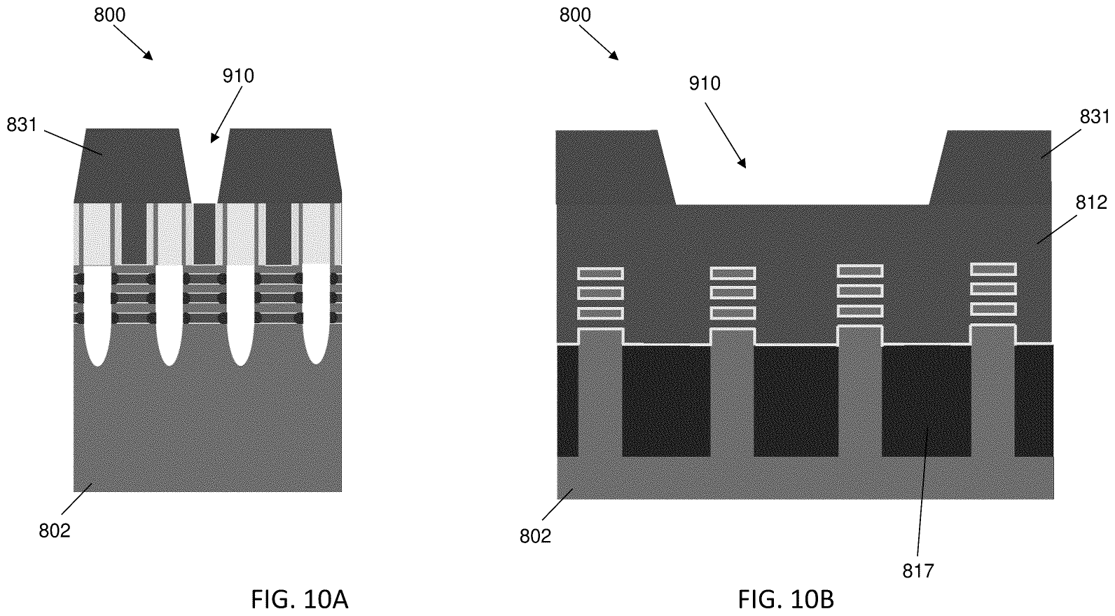

The method 700 proceeds to block 704 where the hard mask layer is patterned. With reference to FIGS. 8A/8B, 9A/9B, and 10A/10B, in an embodiment of block 704, a tri-layer masking element 902 is formed. In some embodiments, the tri-layer masking clement 902 includes a patterned photoresist material layer 904, a middle layer 906 (e.g., including a silicon-containing spin-on coated material, such as spin-on glass), and a bottom layer 908 (e.g., including an organic spin-on coated material, such as spin-on carbon). By way of example, the photoresist material 904 is patterned by using an appropriate photolithography process (e.g., coat, expose, develop, etc.). After forming the tri-layer masking clement 902 with the patterned photoresist material 904, an etching process may be performed to remove portions of the middle layer 906, the bottom layer 908, and the hard mask layer 831 underlying the openings in the masking element 902. The etching process may include a dry etching process (e.g., such as a plasma etch). In some cases, the etching process may alternatively or additionally include a wet etching process. As shown in FIGS. 10A/10B, the etching process serves to form an opening 910 in the hard mask layer 831. After patterning the hard mask layer 831, remaining portions of the masking element 902 may be removed.

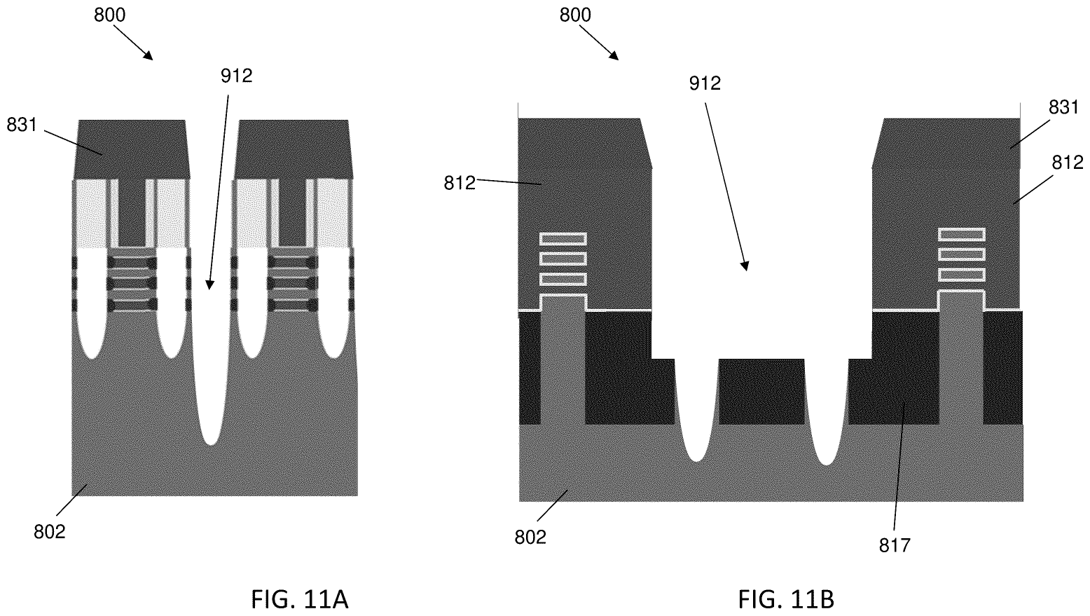

The method 700 proceeds to block 706 where a CMODE cut process is performed. With reference to FIGS. 10A/10B and 11A/11B, in an embodiment of block 706, an etching process is performed through the opening 910 in the hard mask layer 831 to form a trench 912. The etching process may include a dry etch, a wet etch, or a combination thereof, in various embodiments. As shown, the etching process to form the trench 912 etches through portions of the gate structure including the metal layer 812, the gate dielectric 808, and at least one active region having a plurality of stacked nanosheet channel layers 806. Thus, in some cases, the CMODE cut process may also be referred to as a nanosheet cut process (or sheet cut process). In various embodiments, as shown, the trench 912 extends into the underlying substrate 802. Moreover, in some embodiments, the trench 912 extends deeper into the underlying substrate 802 than a bottom surface of the STI feature 817 (as shown in FIG. 11B).

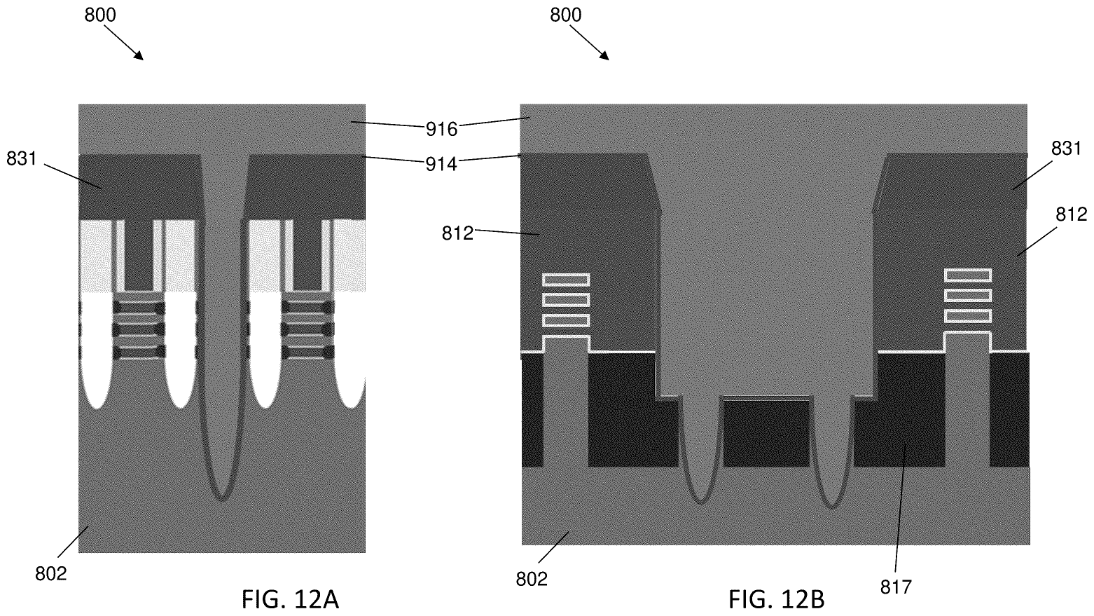

The method 700 proceeds to block 708 where a CMODE refill process and a planarization process are performed. With reference to FIGS. 11A/11B and 12A/12B, in an embodiment of block 708, a CMODE refill process is performed to fill the previously formed trench 912. As shown, the refill process of block 708 may form a multilayer structure including dielectric layers 914, 916, where the dielectric layers 914, 916 completely fill the trench 912 and are also formed over a top surface of the semiconductor device 800. In some embodiments, the dielectric layers 914, 916 include a nitride layer such as SiN, SiO₂, silicon oxynitride, FSG, a low-K dielectric, combinations thereof, and/or other suitable materials known in the art. In various examples, the dielectric layers 914, 916 may be deposited by a CVD process, an SACVD process, a flowable CVD process, an ALD process, a PVD process, and/or other suitable process. With reference to FIGS. 12A/12B and 13A/13B, in a further embodiment of block 708 and after deposition of the dielectric layers 914, 916, a planarization process (e.g., such as a CMP process) may be performed to remove excess materials, including the patterned hard mask layer 831. Thus, the refilled trench 912 provides an isolation structure 920 that provides isolation between adjacent portions of the metal layer 812 of a respective gate structure. It will thereby be understood that the isolation structure 920, in some embodiments, may be similar to and/or provide substantially the same function as the isolation structures 420, discussed above with reference to FIG. 4E. After forming the isolation structure 920, further processing may be formed, such as described above with reference to block 312 of the method 300.

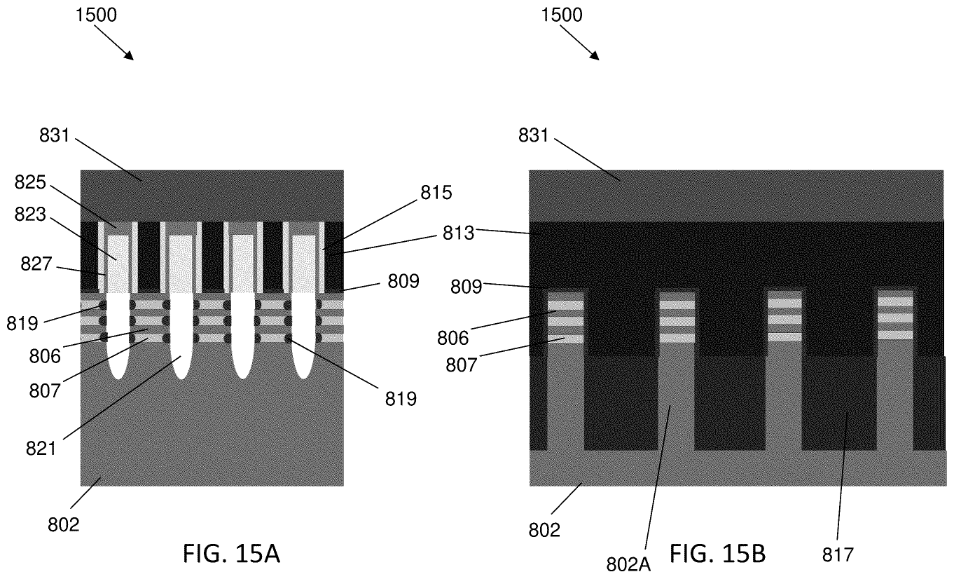

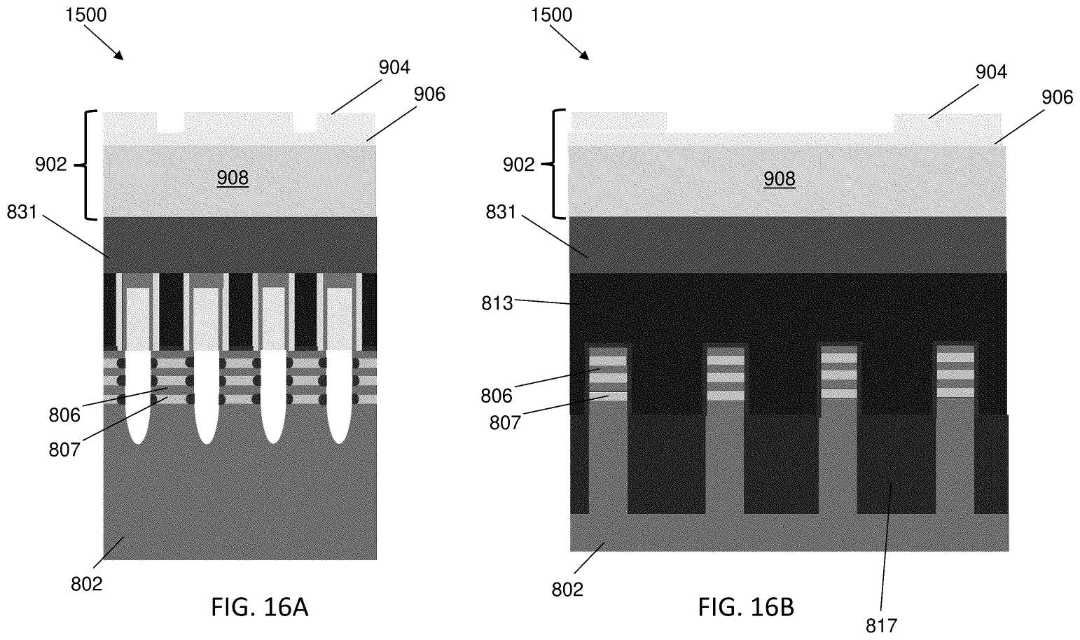

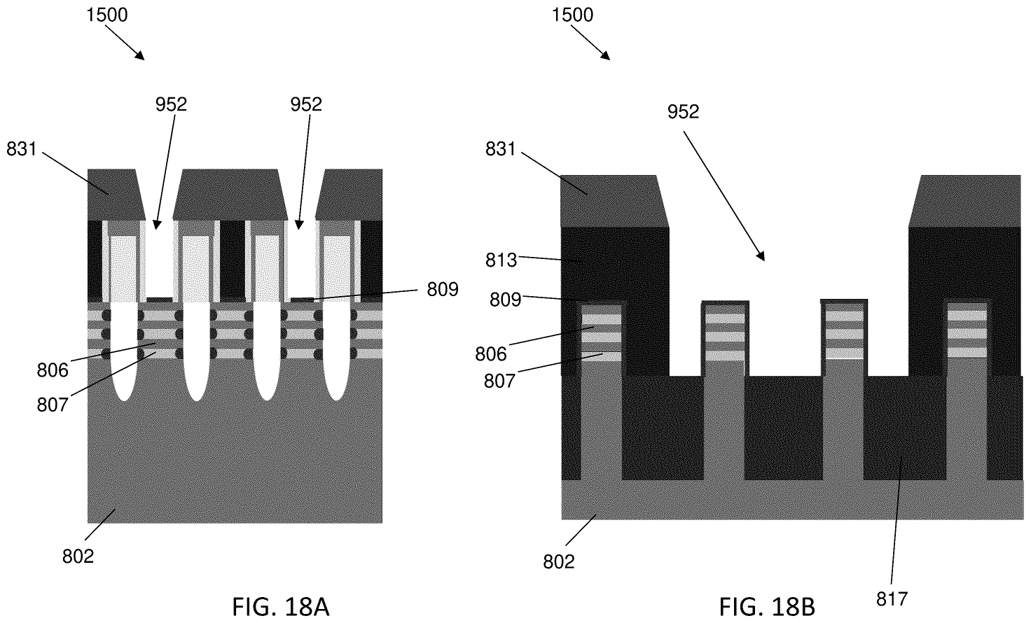

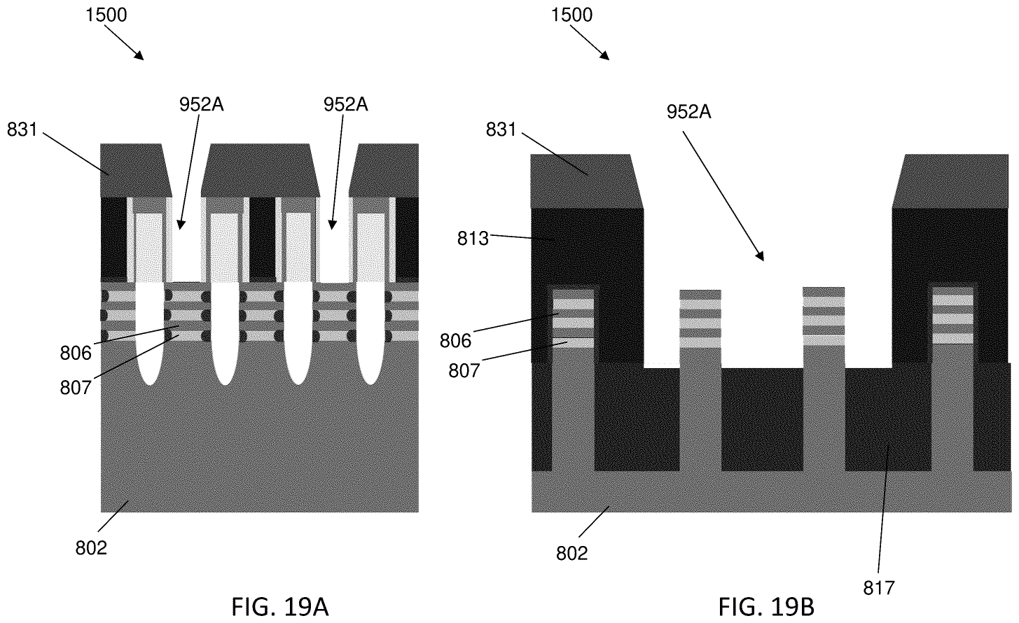

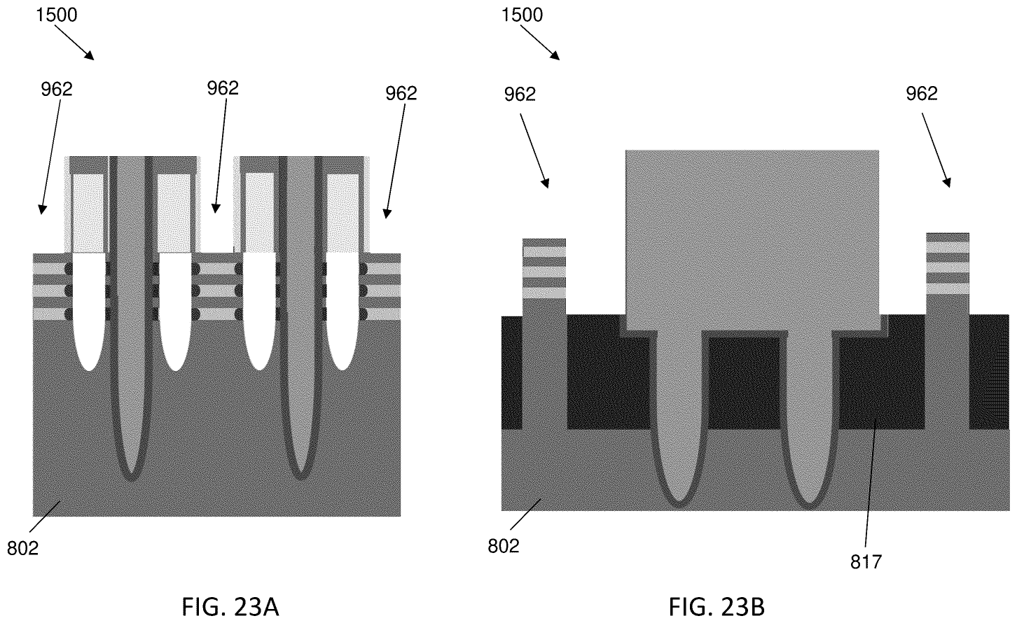

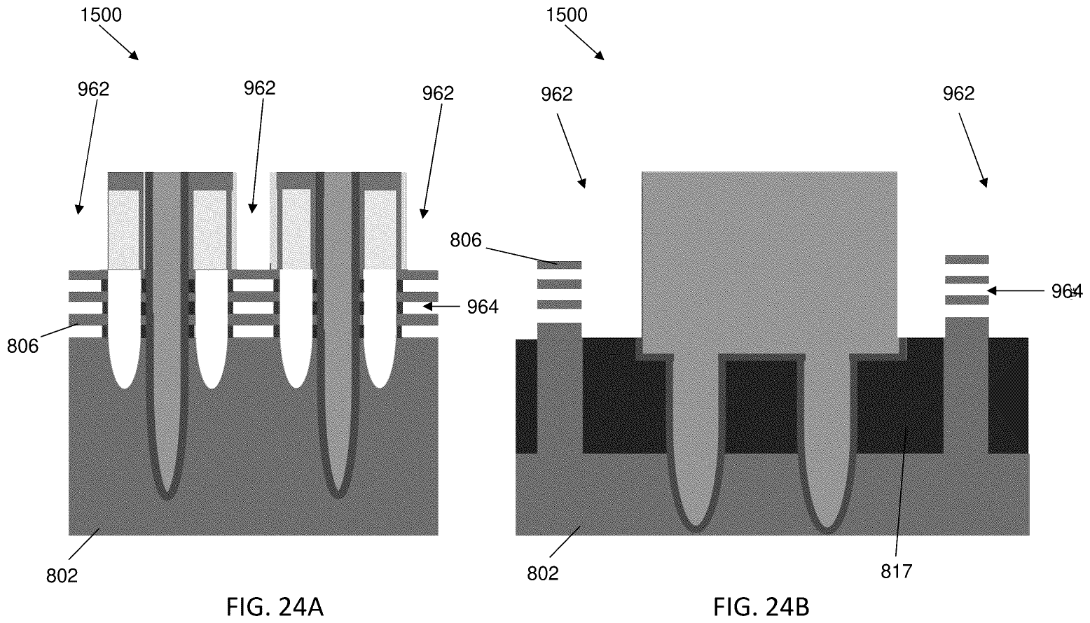

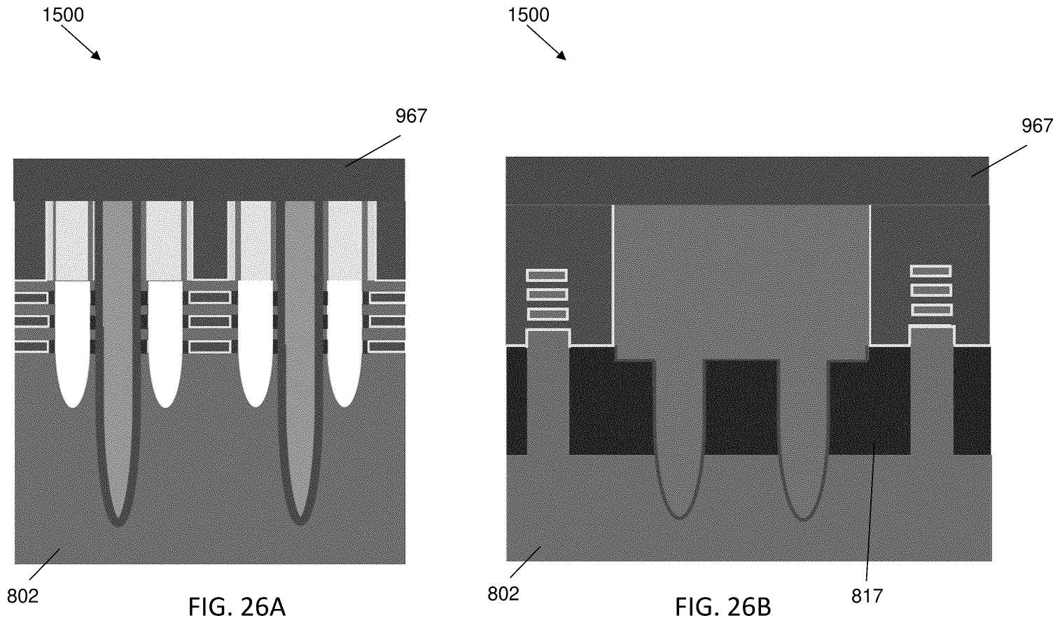

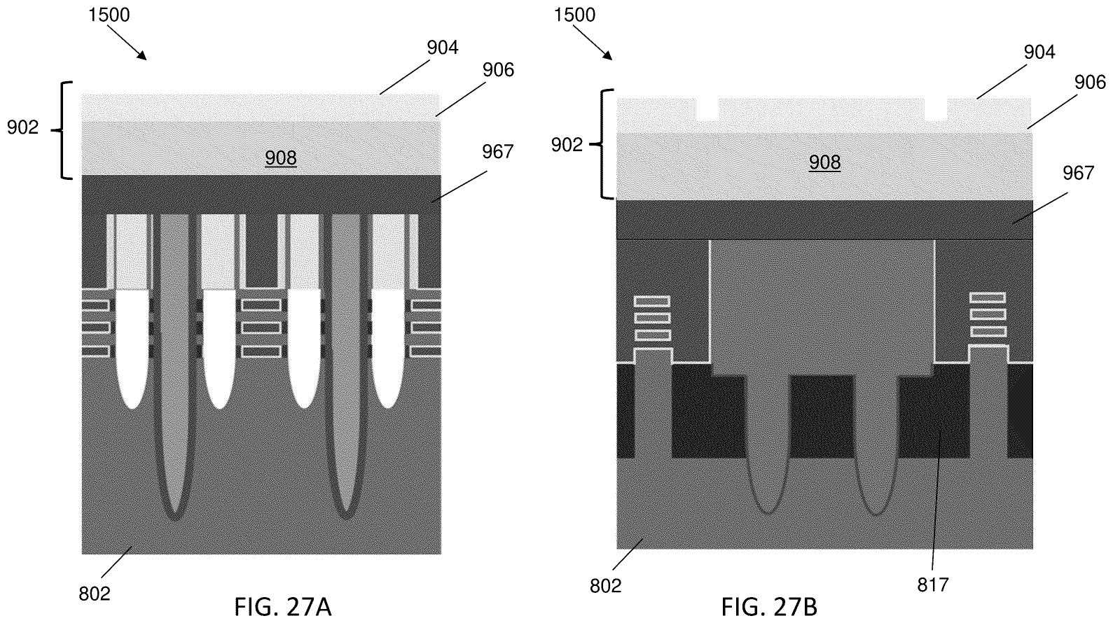

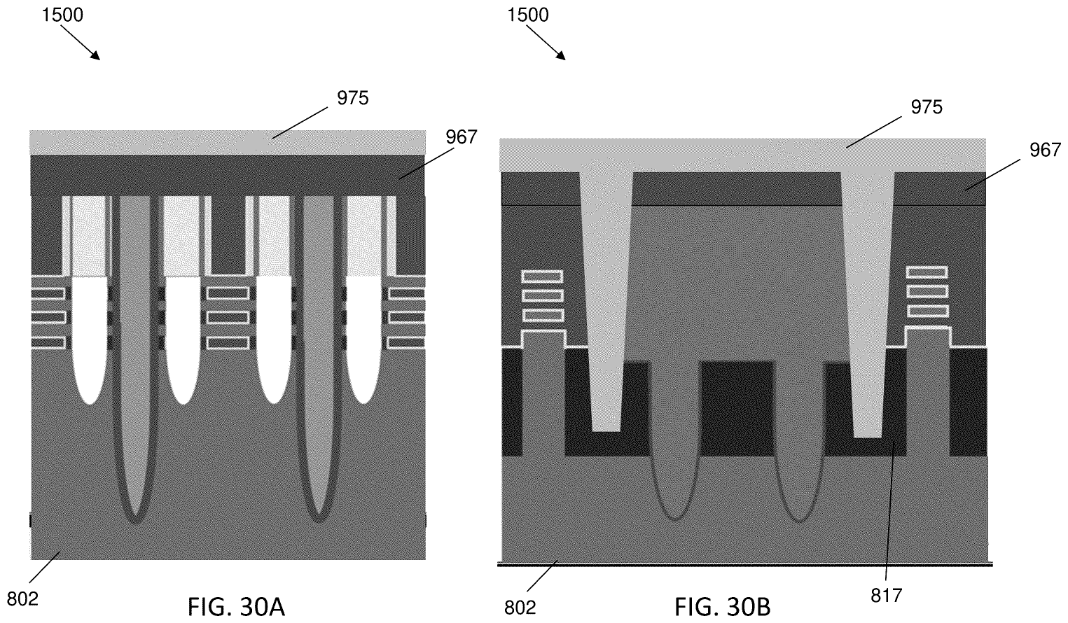

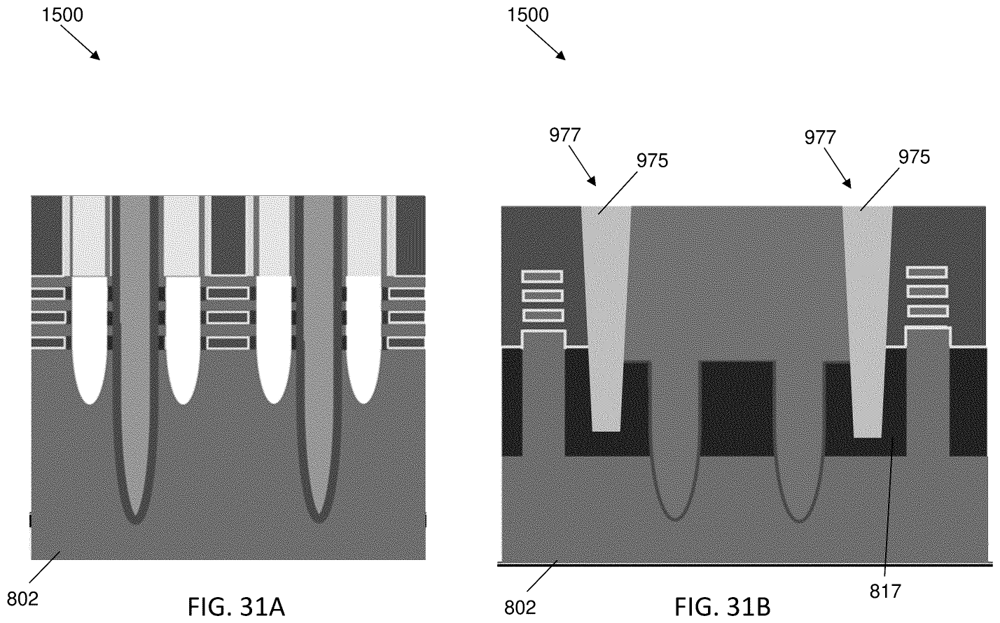

Referring now to FIG. 14, illustrated therein is a method 1400 of fabricating a semiconductor device 1500 using a CPODE patterning process, in accordance with various embodiments. In some embodiments, the method 1400 provides the CPODE patterning process, discussed above with reference to block 504 of the method 500. Additionally, and in some embodiments, the method 1400 provides the replacement gate process and the optional CMG patterning process, discussed above with reference to blocks 308, 508 of the method 500. The method 1400 is discussed below with reference to a semiconductor device including a GAA transistor. However, it will be understood that aspects of the method 1400 may be equally applied to other types of multi-gate devices such as FinFETs, as discussed above, without departing from the scope of the present disclosure. The method 1400 is described below with reference to FIGS. 15A/15B-31A/31B, which provide cross-sectional views of the semiconductor device 1500 at various stages of fabrication according to the method 1400. In particular, FIGS. 15A-31A provide cross-sectional views of an embodiment of the semiconductor device 1500 along a plane substantially parallel to a plane defined by section AA′ of FIG. 1. In addition, FIGS. 15B-31B provide cross-sectional views of an embodiment of the semiconductor device 1500 along a plane substantially parallel to a plane defined by section BB′ of FIG. 1. In some embodiments, the method 1400 may be used to fabricate the multi-gate device 100 described above with reference to FIG. 1 or the SRAM cell 200 described above with reference to FIG. 2. Thus, one or more aspects discussed above with reference to the multi-gate device 100, or with reference to the SRAM cell 200, may also apply to the method 1400 and to the semiconductor device 1500. It is understood that the method 1400 includes steps having features of a CMOS technology process flow and thus, are only described briefly herein. Also, additional steps may be performed before, after, and/or during the method 1400. Further, the method 1400 is similar in various respects to the method 700, discussed above. Thus, some aspects of the method 1400 which have previously been described during the discussion of the method 700 are only briefly described below. In addition, and for clarity of discussion, reference numerals used in the discussion of the method 700 may be repeated below in the discussion of the method 1400.

The method 1400 begins at block 1402 where a partially fabricated multi-gate device is provided. With reference to FIGS. 15A/15B, in an embodiment of block 1402, a partially fabricated semiconductor device 1500 is provided. The semiconductor device 1500 is formed on a substrate 802, which may be substantially the same as described above. The substrate 802 may include active regions having a plurality of stacked nanosheet channel layers 806 disposed over the substrate 802. Further, since the device 1500 is provided before the replacement gate process, the plurality of stacked nanosheet channel layers 806 (e.g., Si layers) are interposed by a plurality of dummy epitaxial layers 807 (e.g., SiGe layers). The active regions may be the active regions 402, 404, discussed above, in some embodiments. In various embodiments, each of the active regions includes a substrate portion 802A formed from the substrate 802 and the plurality of stacked nanosheet channel layers 806 interposed by the plurality of dummy epitaxial layers 807.

STI features 817 may also be formed interposing the adjacent active regions. In some embodiments, the STI features 817 include SiO₂, silicon nitride, silicon oxynitride, fluorine-doped silicate glass (FSG), a low-K dielectric, combinations thereof, and/or other suitable materials known in the art. In various examples, the dielectric layer used to form the STI features 817 may be deposited by a CVD process, a subatmospheric CVD (SACVD) process, a flowable CVD process, an ALD process, a PVD process, and/or other suitable process.

The semiconductor device 1500 further includes dummy gate structures, which may be similar to the dummy gate structures 406, described above. The dummy gate structures are replaced at a later stage of processing by a high-K/metal gate stack, as previously described. The dummy gate structure may include a dummy gate dielectric 809 and a dummy gate electrode 813 (e.g., such as a polysilicon layer) formed over the dummy gate dielectric 809.

As shown, the semiconductor device 1500 also includes a spacer layer 815 formed on sidewalls of a top portion of each of the dummy gate structures. After a subsequent replacement gate process, the spacer layer 815 may remain disposed on sidewalls of a top portion of the high-K/metal gate stack. In some examples, the spacer layer 815 is substantially the same as described above. The semiconductor device 1500 further includes inner spacers 819 disposed between adjacent channels of the nanosheet channel layers 806, at lateral ends of the nanosheet channel layers 806. The inner spacers 819 may be substantially the same as described above. The semiconductor device 1500 may further includes source/drain features 821 formed in source/drain regions adjacent to and on either side of the dummy gate structure of each of the GAA transistors. In various embodiments, the source/drain features 821 may be substantially the same as described above.

The semiconductor device 1500 may further include an inter-layer dielectric (ILD) layer 823. In some embodiments, a contact etch stop layer (CESL) 827 is formed prior to forming the ILD layer 823. In some examples, a nitrogen-containing layer 825 (e.g., such as a silicon nitride layer 825) is also formed over the ILD layer 823. The nitrogen-containing layer 825 may be formed by a CVD process, a PECVD process, and/or other suitable deposition processes. In some embodiments, a hard mask layer 831 (e.g., such as SiN) may be formed over the semiconductor device 1500. In various embodiments, the ILD layer 823, the CESL 827, and the hard mask layer 831 may be substantially the same as described above.

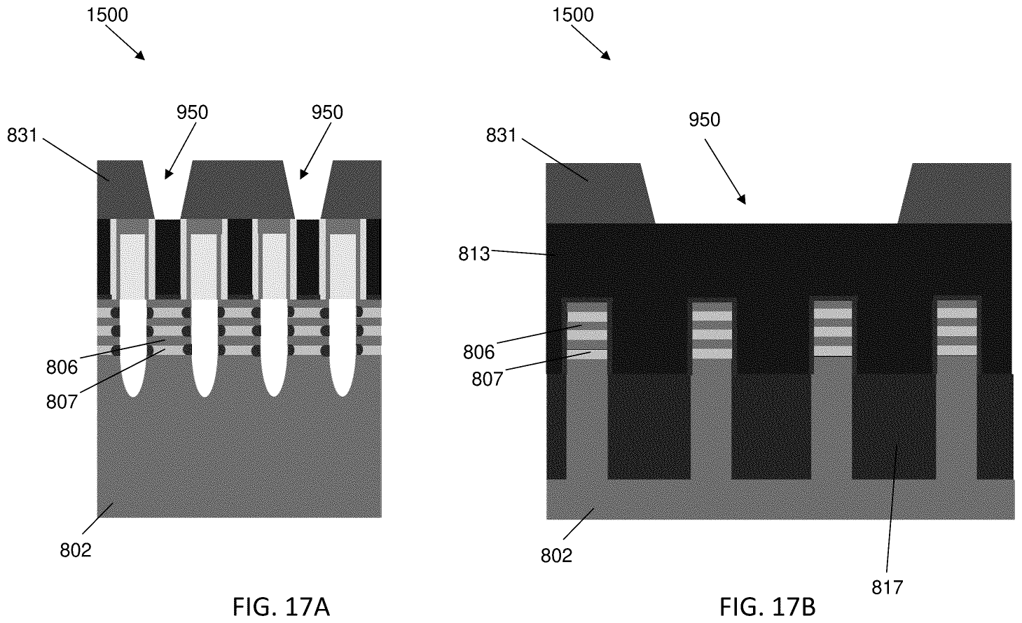

The method 1400 proceeds to block 1404 where the hard mask layer is patterned. With reference to FIGS. 15A/15B, 16A/16B, and 17A/17B, in an embodiment of block 1404, a tri-layer masking element 902 is formed. In some embodiments, the tri-layer masking element 902 includes a patterned photoresist material layer 904, a middle layer 906 (e.g., including a silicon-containing spin-on coated material, such as spin-on glass), and a bottom layer 908 (e.g., including an organic spin-on coated material, such as spin-on carbon), such as described above. After forming the tri-layer masking element 902 with the patterned photoresist material 904, an etching process may be performed to remove portions of the middle layer 906, the bottom layer 908, and the hard mask layer 831 underlying the openings in the masking element 902. The etching process may include a dry etching process (e.g., such as a plasma etch). In some cases, the etching process may alternatively or additionally include a wet etching process. As shown in FIGS. 17A/17B, the etching process serves to form openings 950 in the hard mask layer 831. After patterning the hard mask layer 831, remaining portions of the masking clement 902 may be removed.

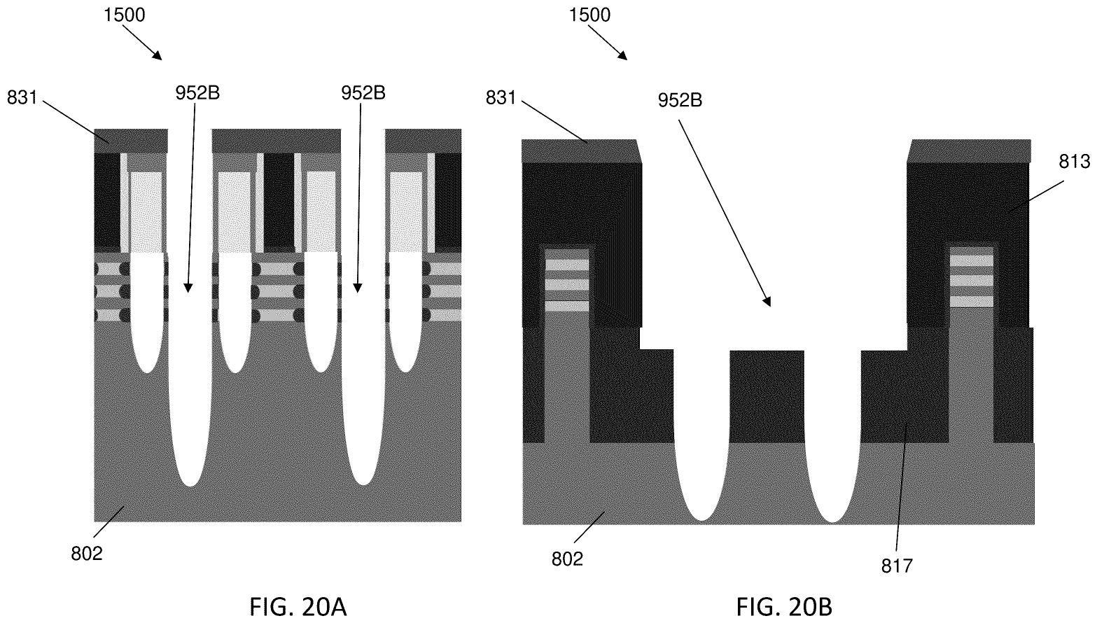

The method 1400 proceeds to block 1406 where a CPODE cut process is performed. With reference to FIGS. 17A/17B, 18A/18B, 19A/19B, and 20A/20B, in an embodiment of block 1406, etching processes are performed through the openings 950 in the hard mask layer 831, as described below. The etching processes may include a dry etch, a wet etch, or a combination thereof, in various embodiments. Initially, a first etching process may be performed to remove a portion of the dummy gate electrode 813 (e.g., polysilicon layer) to form a trench 952 that exposes the dummy gate dielectric 809. Thereafter, a second etching process may be performed to remove the dummy gate dielectric 809 and form an expanded trench 952A. As shown, the expanded trench 952A exposes two active regions having a plurality of stacked nanosheet channel layers 806 interposed by a plurality of dummy epitaxial layers 807. More generally, at least one active region will be exposed. In some embodiments, a third etching process is then performed to remove the plurality of stacked nanosheet channel layers 806 and the interposing plurality of dummy epitaxial layers 807 from the exposed active regions, thereby forming a further enlarged trench 952B. In various embodiments, as shown, the trench 952B extends into the underlying substrate 802. Moreover, in some embodiments, the trench 952B extends deeper into the underlying substrate 802 than a bottom surface of the STI feature 817 (as shown in FIG. 20B).

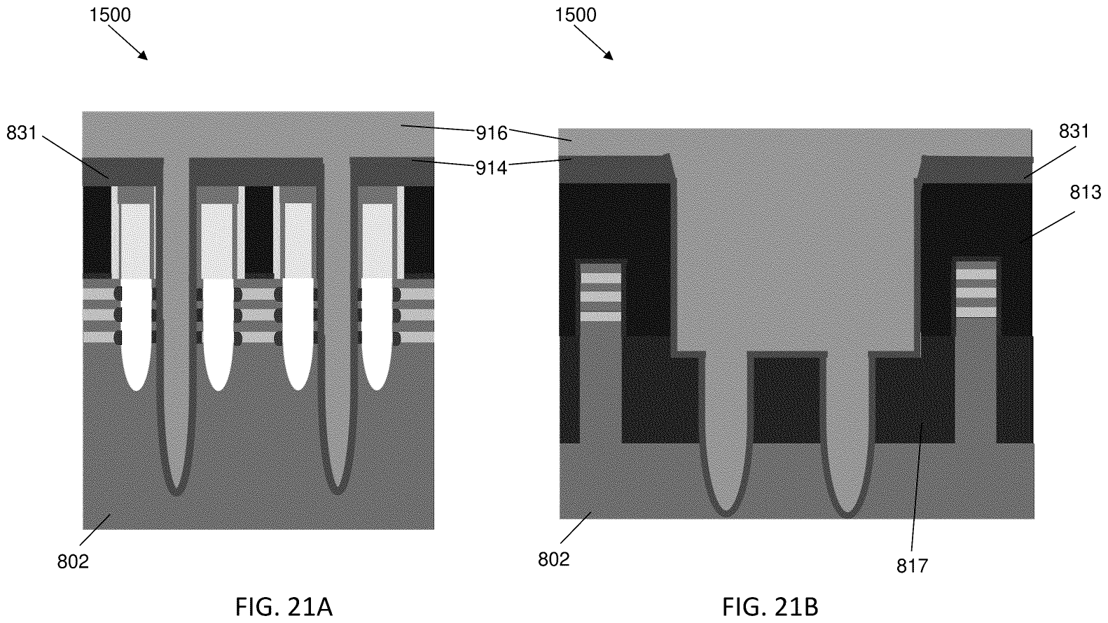

The method 1400 proceeds to block 1408 where a CPODE refill process and a planarization process are performed. With reference to FIGS. 20A/20B and 21A/21B, in an embodiment of block 1408, a CPODE refill process is performed to fill the previously formed trench 952B. As shown, the refill process of block 1408 may form a multilayer structure including dielectric layers 914, 916, where the dielectric layers 914, 916 completely fill the trench 952B and are also formed over a top surface of the semiconductor device 1500. In some embodiments, the dielectric layers 914, 916 include a nitride layer such as SiN, SiO₂, silicon oxynitride, FSG, a low-K dielectric, combinations thereof, and/or other suitable materials known in the art. In various examples, the dielectric layers 914, 916 may be deposited by a CVD process, an SACVD process, a flowable CVD process, an ALD process, a PVD process, and/or other suitable process. With reference to FIGS. 21A/21B and 22A/22B, in a further embodiment of block 1408 and after deposition of the dielectric layers 914, 916, a planarization process (e.g., such as a CMP process) may be performed to remove excess materials, including the patterned hard mask layer 831. Thus, the refilled trench 952B provides an isolation structure 960 that provides isolation between adjacent portions of the dummy gate electrode 813 of a respective gate structure (that will be replaced at a later stage of processing by a metal layer of a high-K/metal gate stack). It will thereby be understood that the isolation structure 960, in some embodiments, may be similar to and/or provide substantially the same function as the isolation structures 420, discussed above with reference to FIG. 6D.

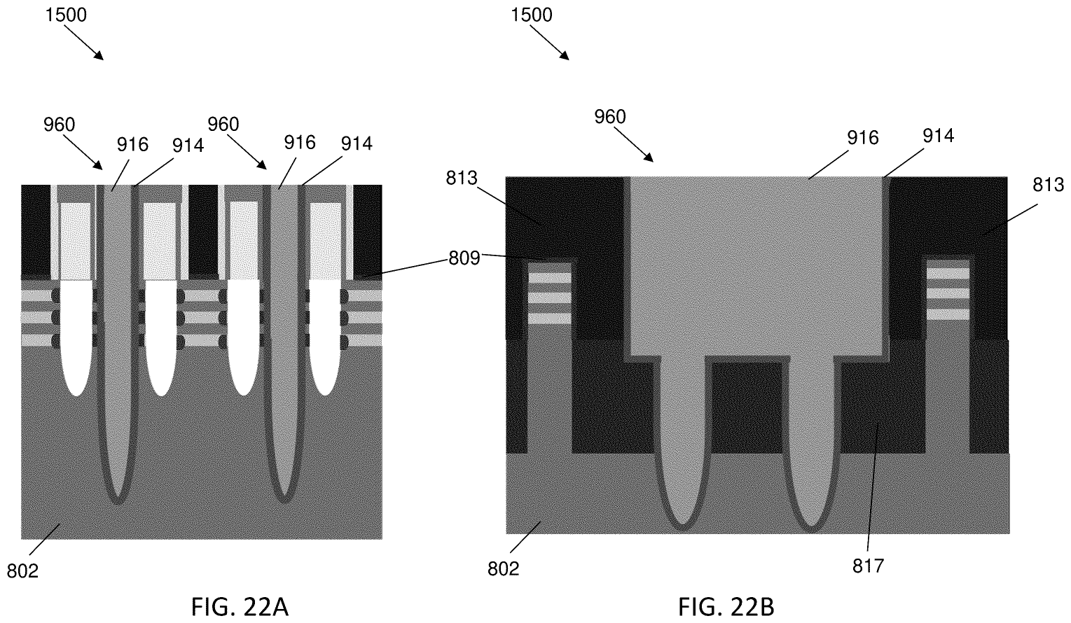

After performing the CPODE patterning process, as discussed above, the method 1400 proceeds to block 1410 where a replacement gate process is performed. In some embodiments, the replacement gate process of block 1410 may be similar to the replacement gate process discussed above with reference to block 308 of the method 500. With reference to FIGS. 22A/22B, 23A/23B, 24A/24B, and 25A/25B, in an embodiment of block 1410, a replacement gate process is performed to replace the dummy gate structures with a high-K/metal gate stack, in a similar manner as discussed above. Initially, in some embodiments, one or more etching processes are performed to remove remaining portions of the dummy gate electrode 813 (e.g., polysilicon layer) and the dummy gate dielectric 809 to form a trenches 962 that expose active regions including the plurality of stacked nanosheet channel layers 806 interposed by the plurality of dummy epitaxial layers 807. The etching processes may include a dry etch, a wet etch, or a combination thereof, in various examples.

In some embodiments, a channel release process may be performed after removal of the dummy gate structures (including the dummy gate electrode 813 and the dummy gate dielectric 809) to remove the dummy epitaxial layers 807 disposed between the nanosheet channel layers 806. In some cases, the dummy epitaxial layers 807 may be removed through the trenches 962 using a selective etching process (e.g., such as a selective dry etch, a wet etch, or a combination thereof). As shown, removal of the dummy epitaxial layers 807 also serves to form gaps 964 between adjacent ones of the nanosheet channel layers 806.

After the channel release process and formation of the gaps 964, high-K/metal gate stacks (such as the high-K/metal gate stacks 412, described above) are formed in substrate regions previously occupied by the dummy gate structures. In some embodiments, the gate structures may form the gates associated with the multi-channels provided by the nanosheet channel layers 806 in the channel region of the respective GAA devices. The gate structure may include a gate dielectric 808 including an IL and a high-K gate dielectric layer formed over the IL. In various embodiments, the IL and the high-K gate dielectric may include one or more of the material compositions described above. In some embodiments, the gate structure may further include a metal gate having a metal layer 812 formed over the gate dielectric 808. In some cases, the metal layer 812 may be substantially the same as the metal layer 416, discussed above. In the present example, the gate structure includes portions that interpose each of the nanosheet channel layers 806 (e.g., filling the gaps 964), where the nanosheet channel layers 806 each provide semiconductor channel layers for respective GAA transistors. Additionally, in some examples, another metal layer (e.g., such as a selectively-grown tungsten (W) layer) may be formed over the metal layer 812. In some cases, the selectively-grown W layer may include a FFW layer. In various examples, the selectively-grown W layer may serve as an etch-stop layer and may also provide reduced contact resistance (e.g., to the metal layer 812). It is also noted that the portion of the gate dielectric 808 formed at interface 965 between the metal layer 812 and the isolation structure 960 may correspond to the portions of the high-K dielectric layer 414 disposed along the entirety of the interface between the high-K/metal gate stacks 412 and the isolation structures 420 within the regions 602, as illustrated in FIG. 6E.

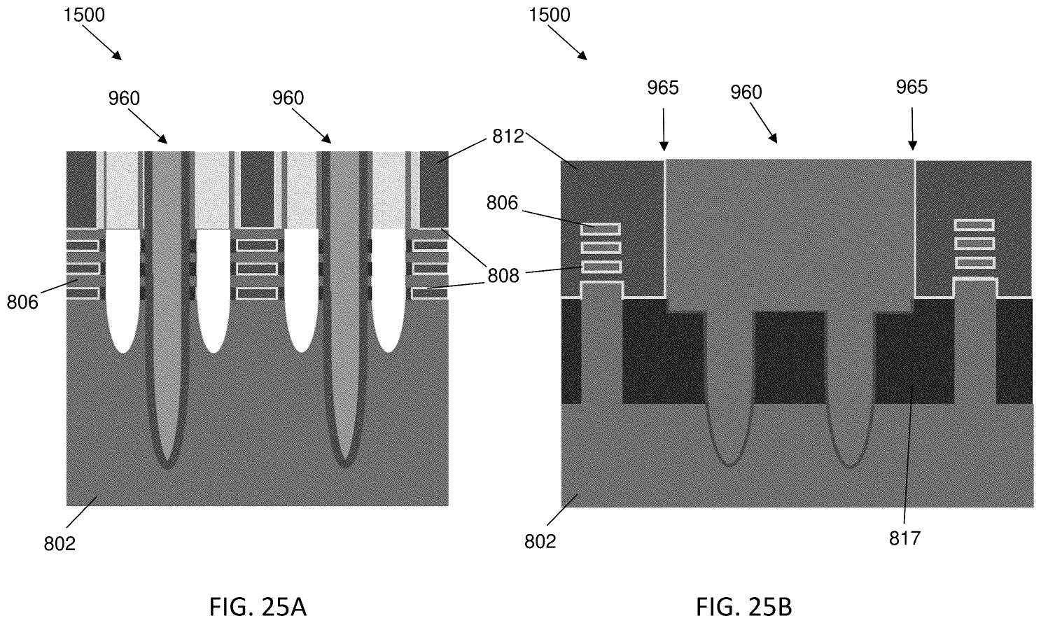

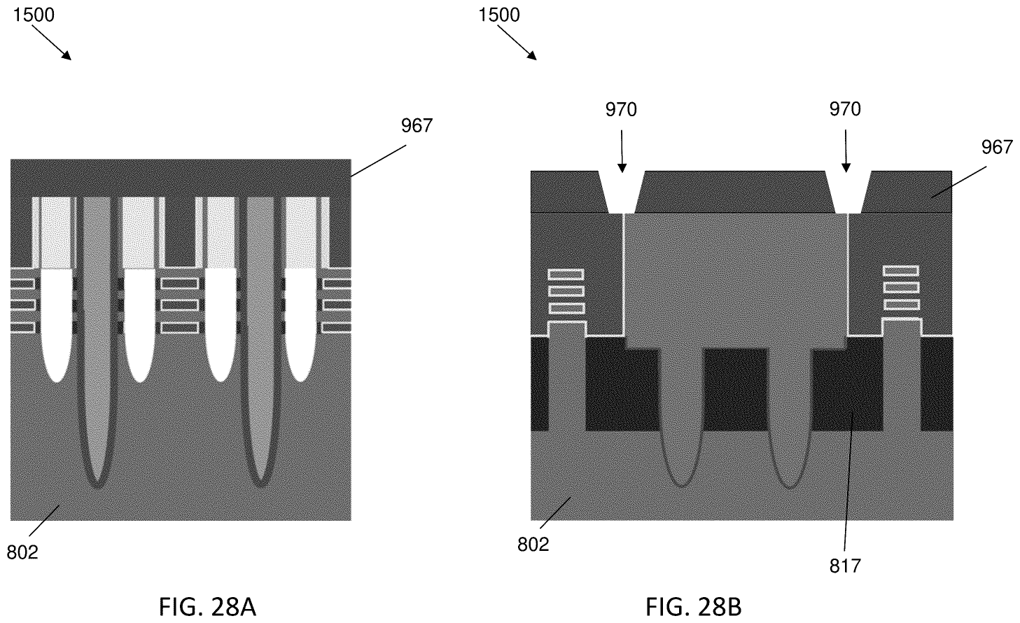

After the replacement gate process, the method 1400 may optionally proceed to block 1412 where a CMG patterning process is performed. The optional CMG patterning process may be performed to mitigate MBE-induced parasitic capacitance, as discussed above. In some embodiments, the CMG patterning process of block 1412 may be similar to the CMG patterning process discussed above with reference to block 508 of the method 500. With reference to FIGS. 25A/25B, 26A/26B, 27A/27B, 28A/28B, 29A/29B, 30A/30B, and 31A/31B, in an embodiment of block 1412, a CMG patterning process is used to remove the portions of the gate dielectric 808 (including a high-K dielectric layer) formed at interface 965, to reduce parasitic capacitance. Initially, in some embodiments, a hard mask layer 967 is formed over the semiconductor device 1500. The hard mask layer 967 may be substantially the same as the hard mask layer 831, discussed above. Thereafter, a tri-layer masking element 902, such as described above, may be formed over the hard mask layer 967. After forming the tri-layer masking element 902, an etching process may be performed to remove portions of the middle layer 906, the bottom layer 908, and the hard mask layer 967 underlying the openings in the masking element 902. The etching process may include a dry etching process (e.g., such as a plasma etch). In some cases, the etching process may alternatively or additionally include a wet etching process. As shown in FIG. 28B, the etching process serves to form openings 970 in the hard mask layer 967 that expose the interface 965. After patterning the hard mask layer 967, remaining portions of the masking element 902 may be removed.

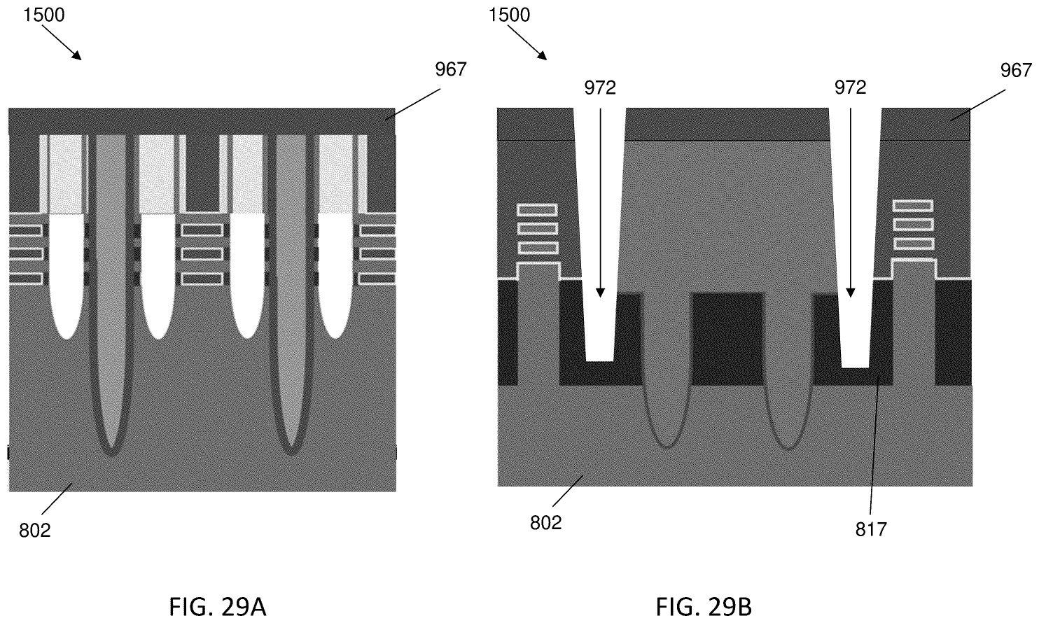

After forming the openings 970 in the hard mask layer 967, a CMG cut process is performed. In some embodiments, the CMG cut process may be performed through the openings 970 using a dry etch, a wet etch, or a combination thereof. In particular, the CMG cut process is performed to remove the portions of the gate dielectric 808 (including a high-K dielectric layer) formed at the interface 965, as well as portions of the metal layer 812 and the isolation structure 960 on either side of the interface 965, thereby forming trenches 972. As shown, the trenches 972 extend into the STI features 817. However, the trenches 972 do not extend beyond a bottom surface of the STI features 817. Generally, the bottom surface of the STI features 817 extends deeper into the substrate 802 than the trenches 972 formed by the CMG cut process. Moreover, in various embodiments, the trench 952B (used to form the isolation structure 960) extends deeper into the underlying substrate 802 than both a bottom surface of the STI feature 817 and a bottom surface of the trenches 972 (as shown in FIG. 29B). After forming the trenches 972, a CMG refill process and a planarization process are performed. For example, the CMG refill process may include forming one or more dielectric layers 975 within the trenches 972 to completely fill the trenches 972. The one or more dielectric layers 975 may also be formed over a top surface of the semiconductor device 1500. In some embodiments, the one or more dielectric layers 975 may include a nitride layer such as SiN, SiO₂, silicon oxynitride, FSG, a low-K dielectric, combinations thereof, and/or other suitable materials known in the art. In various examples, the one or more dielectric layers 975 may be deposited by a CVD process, an SACVD process, a flowable CVD process, an ALD process, a PVD process, and/or other suitable process. Thereafter, in some embodiments, a planarization process (e.g., such as a CMP process) may be performed to remove excess materials, including the patterned hard mask layer 967. Thus, the refilled trenches 972 provides CMG isolation structures 977 that effectively serve to mitigate MBE-induced parasitic capacitance. It will thereby be understood that the CMG isolation structures 977, in some embodiments, may be similar to and/or provide substantially the same function as the CMG isolation structures 604, 606, 608, and 610, discussed above with reference to FIGS. 6F-6H. After forming the CMG isolation structures 977, further processing may be performed, such as described above with reference to block 312 of the method 500. In some cases, if the optional CMG patterning process of block 1412 is skipped, the method 1400 may proceed from block 1410 directly to performing further processing, such as described with reference to block 312 of the method 500.

With respect to the description provided herein, disclosed are methods and structures for performing isolation patterning processes in highly-scaled CMOS circuits, to address various existing challenges (such as minimization of LDEs). While not limited thereto, aspects of the present disclosure may be used to perform isolation structures within, and thus to pattern, SRAM circuits. In various embodiments, the disclosed isolation patterning processes may be performed using a CMODE patterning process, a CPODE patterning process, or a combination of a CPODE patterning process and a CMG patterning process. As part of the CMODE process, and after formation of a metal gate stack, a trench may be formed through a portion of the metal gate stack and extending into the substrate, and the trench is filled with a dielectric material, thereby providing isolation between adjacent portions of the metal gate stack. As part of the CPODE process, after formation of a dummy poly gate and prior to forming a metal gate stack, a trench may be formed through a portion of the dummy poly gate and extending into the substrate, and the trench is filled with a dielectric material, thereby providing isolation between adjacent portions of the dummy poly gate. In some cases, when a CPODE process is performed and after replacing the dummy poly gate with a metal gate stack, a CMG process may be performed to remove high-K gate dielectric portions from metal line end regions of the metal gate stack in order to reduce parasitic capacitance by minimizing MBEs. Embodiments of the present disclosure thus effectively mitigate LDEs, as compared to existing implementations. Other embodiments and advantages will be evident to those skilled in the art upon reading the present disclosure.

Thus, one of the embodiments of the present disclosure described a method that includes defining a plurality of active regions in a substrate, the plurality of active regions extending in a first direction in a top-down view. In some embodiments, the method further includes forming a plurality of dummy gate structures over the plurality of active regions, the plurality of dummy gate structures extending in a second direction in the top-down view, the second direction perpendicular to the first direction. In some embodiments, the method further includes forming a plurality of source/drain features in source/drain regions adjacent to and on either side of each dummy gate structure of the plurality of dummy gate structures. In some embodiments, the method further includes replacing the plurality of dummy gate structures with a plurality of high-K/metal gate stacks. In some embodiments, the method further includes forming a first isolation structure within a first high-K/metal gate stack of the plurality of high-K/metal gate stacks, where the first isolation structure has first and second source/drain features of the plurality of source/drain features disposed on either side of the first isolation structure.

In another of the embodiments, discussed is a method that includes defining a plurality of active regions in a substrate, the plurality of active regions extending in a first direction in a top-down view. In some embodiments, the method further includes forming a plurality of dummy gate structures over the plurality of active regions, the plurality of dummy gate structures extending in a second direction in the top-down view, the second direction perpendicular to the first direction. In some embodiments, the method further includes forming a plurality of source/drain features in source/drain regions adjacent to and on either side of each dummy gate structure of the plurality of dummy gate structures. In some embodiments, the method further includes after forming the plurality of source/drain features, forming first and second isolation structures within respective first and second dummy gate structures of the plurality of dummy gate structures, where the first and second isolation structures are disposed on opposing sides of a source/drain feature of the plurality of source/drain features. In some embodiments, the method further includes after forming the first and second isolation structures, replacing the plurality of dummy gate structures with a plurality of high-K/metal gate stacks.

In yet another of the embodiments, discussed is a semiconductor device including a plurality of active regions in a substrate, the plurality of active regions extending in a first direction in a top-down view and providing an array of repeating shapes. In some embodiments, the semiconductor device further includes a plurality of high-K/metal gate stacks over the plurality of active regions, the plurality of high-K/metal gate stacks extending in a second direction in the top-down view, the second direction perpendicular to the first direction. In some embodiments, the semiconductor device further includes a plurality of source/drain features in source/drain regions adjacent to and on either side of each high-K/metal gate stack of the plurality of high-K/metal gate stacks. In some embodiments, the semiconductor device further includes an isolation structure disposed within a high-K/metal gate stack of the plurality of high-K/metal gate stacks, where the isolation structure has first and second source/drain features of the plurality of source/drain features disposed on either side of the isolation structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of fabricating a semiconductor device, comprising:
defining a plurality of active regions in a substrate, the plurality of active regions extending in a first direction in a top-down view;
forming a plurality of dummy gate structures over the plurality of active regions, the plurality of dummy gate structures extending in a second direction in the top-down view, the second direction perpendicular to the first direction;
forming a plurality of source/drain features in source/drain regions adjacent to and on either side of each dummy gate structure of the plurality of dummy gate structures;
replacing the plurality of dummy gate structures with a plurality of high-K/metal gate stacks; and
forming a first isolation structure within a first high-K/metal gate stack of the plurality of high-K/metal gate stacks, wherein the first isolation structure has first and second source/drain features of the plurality of source/drain features disposed on either side of the first isolation structure.

2. The method of claim 1, wherein the plurality of active regions include fins extending from the substrate.

3. The method of claim 1, wherein the plurality of active regions include a plurality of stacked nanosheets disposed over the substrate.

4. The method of claim 1, wherein prior to the forming the plurality of dummy gate structures, the substrate includes a symmetric process environment, in the top-down view, including an array of repeating shapes composed of the plurality of active regions.

5. The method of claim 1, wherein prior to forming the plurality of source/drain features, the substrate includes a symmetric process environment, in the top-down view, including a first array of repeating shapes composed of the plurality of active regions and a second array of repeating shapes composed of the plurality of dummy gate structures.

6. The method of claim 1, wherein prior to the replacing the plurality of dummy gate structures with the plurality of high-K/metal gate stacks, the substrate includes a symmetric process environment, in the top-down view, including a first array of repeating shapes composed of the plurality of active regions, a second array of repeating shapes composed of the plurality of dummy gate structures, and a third array of repeating shapes composed of the plurality of source/drain features.

7. The method of claim 1, wherein prior to forming the first isolation structure, the substrate includes a symmetric process environment, in the top-down view, including a first array of repeating shapes composed of the plurality of active regions, a third array of repeating shapes composed of the plurality of source/drain features, and a fourth array of repeating shapes composed of the plurality of high-K/metal gate stacks.

8. The method of claim 1, wherein the plurality of active regions are separated by shallow trench isolation (STI) features, and wherein the first isolation structure extends deeper into the substrate than a bottom surface of the STI features.

9. The method of claim 1, wherein the first isolation structure extends a first distance in the second direction in the top-down view, wherein the first and second source/drain features extend a second distance in the second direction in the top-down view, and wherein the first distance is equal to or greater than the second distance.

10. The method of claim 1, further comprising:
forming a second isolation structure within a second high-K/metal gate stack of the plurality of high-K/metal gate stacks, wherein the first isolation structure and the second isolation structure are disposed on either side of one of the first source/drain feature and the second source/drain feature.

11. The method of claim 1, wherein the first high-K/metal gate stack provides a gate for a pass-gate transistor, a pull-down transistor, or a pull-up transistor of a static random-access memory (SRAM) device.

12. A method of fabricating a semiconductor device, comprising:
defining a plurality of active regions in a substrate, the plurality of active regions extending in a first direction in a top-down view;
forming a plurality of dummy gate structures over the plurality of active regions, the plurality of dummy gate structures extending in a second direction in the top-down view, the second direction perpendicular to the first direction;
forming a plurality of source/drain features in source/drain regions adjacent to and on either side of each dummy gate structure of the plurality of dummy gate structures;
after forming the plurality of source/drain features, forming first and second isolation structures within respective first and second dummy gate structures of the plurality of dummy gate structures, wherein the first and second isolation structures are disposed on opposing sides of a source/drain feature of the plurality of source/drain features;
after forming the first and second isolation structures, replacing the plurality of dummy gate structures with a plurality of high-K/metal gate stacks.

13. The method of claim 12, wherein prior to the forming the plurality of dummy gate structures, the substrate includes a symmetric process environment, in the top-down view, including an array of repeating shapes composed of the plurality of active regions.

14. The method of claim 12, wherein prior to forming the plurality of source/drain features, the substrate includes a symmetric process environment, in the top-down view, including a first array of repeating shapes composed of the plurality of active regions and a second array of repeating shapes composed of the plurality of dummy gate structures.

15. The method of claim 12, wherein prior to the forming the first and second isolation structures, the substrate includes a symmetric process environment, in the top-down view, including a first array of repeating shapes composed of the plurality of active regions, a second array of repeating shapes composed of the plurality of dummy gate structures, and a third array of repeating shapes composed of the plurality of source/drain features.

16. The method of claim 12, wherein the plurality of active regions are separated by shallow trench isolation (STI) features, and wherein the first isolation structure extends deeper into the substrate than a bottom surface of the STI features.

17. The method of claim 12, further comprising:
after the replacing the plurality of dummy gate structures with the plurality of high-K/metal gate stacks, forming a third isolation structure extending in the first direction in the top-down view, the third isolation structure formed within portions of first and second high-K/metal gate stacks of the plurality of high-K/metal gate stacks at an interface between the first and second high-K/metal gate stacks and respective ones of the first and second isolation structures.

18. A semiconductor device, comprising:
a plurality of active regions in a substrate, the plurality of active regions extending in a first direction in a top-down view and providing an array of repeating shapes;
a plurality of high-K/metal gate stacks over the plurality of active regions, the plurality of high-K/metal gate stacks extending in a second direction in the top-down view, the second direction perpendicular to the first direction;
a plurality of source/drain features in source/drain regions adjacent to and on either side of each high-K/metal gate stack of the plurality of high-K/metal gate stacks; and
an isolation structure disposed within a high-K/metal gate stack of the plurality of high-K/metal gate stacks, wherein the isolation structure has first and second source/drain features of the plurality of source/drain features disposed on either side of the isolation structure.

19. The semiconductor device of claim 18, wherein the plurality of active regions are separated by shallow trench isolation (STI) features, and wherein the isolation structure extends deeper into the substrate than a bottom surface of the STI features.

20. The semiconductor device of claim 18, wherein the isolation structure extends a first distance in the second direction in the top-down view, wherein the first and second source/drain features extend a second distance in the second direction in the top-down view, and wherein the first distance is equal to or greater than the second distance.
